(19) United States
(12) Patent Application Publication
(10) Pub. No.: US 2026/0215053 A1
(43) Pub. Date: Jul. 23, 2026

(54) DISPLAY APPARATUS, METHOD OF MANUFACTURING DISPLAY APPARATUS, AND ELECTRONIC DEVICE

(71) Applicant: Samsung Display Co., LTD., Yongin-si (KR)

(72) Inventors: Changil TAE, Yongin-si (KR); Gyujeong LEE, Yongin-si (KR); Hyungil JEON, Yongin-si (KR)

(21) Appl. No.: 19/454,888

(22) Filed: Jan. 21, 2026

(30) Foreign Application Priority Data
Jan. 23, 2025 (KR) 10-2025-0010659

(51) Int. Cl. H10H 29/37; H10H 29/01

(52) U.S. Cl. CPC H10H 29/37; H10H 29/012

(57) ABSTRACT

A display apparatus includes a display area and a non-display area outside the display area, and the display apparatus includes a first island portion positioned in the display area and in which a light-emitting diode is disposed, a second island portion positioned in the non-display area and in which a circuit unit is disposed, a third island portion positioned between the first island portion and the second island portion in the non-display area and in which a line electrically connecting the light-emitting diode to the circuit unit is disposed, and a support column disposed on an upper surface of the third island portion.

This application claims priority to Korean Patent Application No. 10-2025-0010659, filed on January 23, 2025, and all the benefits accruing therefrom under 35 U.S.C. §119, the content of which in its entirety is herein incorporated by reference.

### BACKGROUND

### Technical Field

One or more embodiments of the disclosure relate to an apparatus and method, and more particularly, to a display apparatus, a method of manufacturing the display apparatus, and an electronic device including the display apparatus.

### Background Art

Recently, electronic devices have been widely used. Electronic devices are used in various ways, such as mobile electronic devices and fixed electronic devices, and these electronic devices include a display apparatus capable of providing a user with visual information, such as images or videos, to support various functions.

According to the development of display apparatuses visually displaying electrical signals, various display apparatuses having excellent characteristics, such as reduced thickness, reduced weight, and low power consumption, have been introduced. For example, flexible display apparatuses that can be folded or rolled into a roll shape have been introduced. Recently, research and development on display apparatuses that have various structures, such as stretchable display apparatuses that can be changed into various shapes, have been actively conducted.

The above-mentioned background art is technical information that the inventor possesses for deriving the disclosure or obtains in the process of deriving the disclosure, and is not necessarily known technology disclosed to the general public prior to the filing of the disclosure.

### SUMMARY

### Technical Problem

One or more embodiments of the disclosure provide a display apparatus with improved quality and an electronic device, for example, a flexible display apparatus and an electronic device.

However, these objectives are examples, and the scope of the disclosure is not limited thereto.

### Solution to Problem

According to an aspect of the disclosure, disclosed is a display apparatus including a display area and a non-display area outside the display area, and the display apparatus includes a first island portion positioned in the display area and in which a light-emitting diode is disposed, a second island portion positioned in the non-display area and in which a circuit unit is disposed, a third island portion positioned between the first island portion and the second island portion in the non-display area and in which a line electrically connecting the light-emitting diode to the circuit unit is disposed, and a support column disposed on an upper surface of the third island portion.

In an embodiment, a height from a lower surface of the third island portion to an upper surface of the support column may be greater than a height from a lower surface of the first island portion to an upper surface of the light-emitting diode.

In an embodiment, in a plan view, the support column may be disposed not to overlap the line.

In an embodiment, the support column may include an organic material.

In an embodiment, the support column may include a plurality of support columns, and the plurality of support columns may be disposed adjacent to vertices of the third island portion, respectively, in a plan view.

In an embodiment, the display apparatus may further include a protective column disposed on an upper surface of the second island portion.

In an embodiment, a height from a lower surface of the second island portion to an upper surface of the protective column may be less than a height from a lower surface of the third island portion to an upper surface of the support column.

In an embodiment, in a plan view, the protective column may be disposed not to overlap the circuit unit.

In an embodiment, the protective column may include a plurality of protective columns, and the plurality of protective columns may be disposed along a periphery of the second island portion in a plan view.

In an embodiment, the protective column may include the same material as the support column.

In an embodiment, each of the second island portion and the third island portion may include a substrate and an insulating layer covering the substrate, and each of the support column and the protective column may be disposed on the insulating layer.

In an embodiment, the display apparatus may further include a support portion disposed on an upper portion of the second island portion and covering the circuit unit.

In an embodiment, the support surface may include the same material as the support column.

In an embodiment, the display apparatus may further include a fourth island portion having a same structure as the second island portion and a fifth island portion having a same structure as the third island portion, and the first island portion, the third island portion, the second island portion, the fifth island portion, and the fourth island portion may be sequentially disposed in a direction from the display area toward the non-display area.

According to an aspect of the disclosure, disclosed is a method of manufacturing a display apparatus, the method including preparing a display substrate including a first island portion positioned in a display area, a second island portion positioned in a non-display area outside the display area, and a third island portion between the first island portion and the second island portion, disposing a support column on an upper surface of the third island portion, disposing a protective column on an upper surface of the second island portion, disposing a light-emitting diode on an upper surface of the first island portion, and pressing the display substrate with a pressing plate.

In an embodiment, the pressing plate may press the light-emitting diode in the display area and may be supported by the support column in the non-display area.

In an embodiment, a height from a lower surface of the third island portion to an upper surface of the support column may be greater than a height from a lower surface of the first island portion to an upper surface of the light-emitting diode.

In an embodiment, a height from a lower surface of the second island portion to an upper surface of the protective column may be less than a height from a lower surface of the third island portion to an upper surface of the support column.

In an embodiment, a circuit unit may be disposed in the second island portion, and a line electrically connecting the circuit unit to the first island portion may be disposed in the third island portion.

According to an aspect of the disclosure, disclosed is an electronic device including a display portion, the electronic device including a display apparatus corresponding to the display portion and a frame accommodating the display apparatus, and the display apparatus includes a display area and a non-display area outside the display area, the display apparatus includes a first island portion positioned in the display area and in which a light-emitting diode is disposed, a second island portion positioned in the non-display area and in which a circuit unit is disposed, a third island portion positioned between the first island portion and the second island portion in the non-display area and in which a line electrically connecting the light-emitting diode to the circuit unit is disposed, and a support column disposed on an upper surface of the third island portion.

Other aspects, features, and advantages other than those described above will now become apparent from the following drawings, claims, and the detailed description of the disclosure.

### Advantageous Effects of Invention

According to one or more embodiments of the disclosure, a display apparatus with improved quality by preventing defects occurring during a bonding process of a light-emitting diode and an electronic device including the display apparatus may be provided.

Effects of the disclosure are not limited to the effects mentioned above, and other effects not mentioned will be clearly understood by one of ordinary in the art from the description of the claims.

### BRIEF DESCRIPTION OF DRAWINGS

FIG. 1 is a perspective view schematically illustrating a display apparatus according to an embodiment of the disclosure.

FIGS. 2A and 2B are perspective views each illustrating a state in which the display apparatus of FIG. 1 is stretched in a first direction.

FIG. 2C is a perspective view illustrating a state in which the display apparatus of FIG. 1 is stretched in a second direction.

FIG. 2D is a perspective view illustrating a state in which the display apparatus of FIG. 1 is stretched in the first direction and the second direction.

FIG. 2E is a perspective view illustrating a state in which the display apparatus of FIG. 1 is stretched in a third direction.

FIG. 3 is a schematic plan view of a display apparatus according to an embodiment of the disclosure.

FIG. 4A is an enlarged plan view of a region IV of FIG. 3 as a portion of the display apparatus of FIG. 3, according to an embodiment of the disclosure.

FIG. 4B is an enlarged plan view of the region IV of FIG. 3 as a portion of the display apparatus of FIG. 3, according to an embodiment of the disclosure.

FIG. 5 is a schematic cross-sectional view of a first island portion and a first bridge portion, which are disposed in a display area of a display apparatus according to an embodiment of the disclosure.

FIGS. 6A to 6C are equivalent circuit diagrams each illustrating a sub-pixel of a display apparatus according to an embodiment of the disclosure.

FIG. 7 is an enlarged plan view of a region VII of FIG. 4B as a portion of the display apparatus of FIG. 4B, according to an embodiment of the disclosure.

FIG. 8 is a cross-sectional view schematically illustrating a display apparatus according to an embodiment of the disclosure, corresponding to a cross-section taken along line VIII-VIII' of FIG. 7.

FIGS. 9 and 10 are cross-sectional views schematically illustrating a display apparatus according to other embodiments of the disclosure, corresponding to a cross-section taken along line VIII-VIII' of FIG. 7.

FIG. 11A is a plan view schematically illustrating a display apparatus according to an embodiment of the disclosure, and may be similar to FIG. 7. FIG. 11B is a cross-sectional view schematically illustrating a display apparatus according to an embodiment of the disclosure, corresponding to a cross-section taken along line IX-IX' of FIG. 11A, and may be similar to FIG. 8.

FIGS. 12A to 12C are diagrams schematically illustrating a method of manufacturing a display apparatus according to an embodiment of the disclosure.

FIG. 13A is a perspective view schematically illustrating an electronic device including a display apparatus according to an embodiment of the disclosure.

FIG. 13B is a block diagram schematically illustrating an electronic device including a display apparatus according to an embodiment of the disclosure.

FIGS. 14A to 14I are schematic perspective views showing embodiments of an electronic device including a display apparatus according to an embodiment of the disclosure, respectively.

### DETAILED DESCRIPTION

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as "first," "second," etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as "including" and "having" are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. That is, for example, intervening layers, regions, or elements may be present.

When a layer, region, or component is referred to as being connected to another layer, region, or component, it includes the case of being directly connected to the other layer, region, or component and/or the case of being indirectly connected to the other layer, region, or component with intervening layers, regions, or components therebetween. In addition, when a layer, region, or component is referred to as being electrically connected to another layer, region, or component, it includes the case of being directly electrically connected to the other layer, region, or component and/or the case of being indirectly electrically connected to the other layer, region, or component with intervening layers, region, or components therebetween.

Sizes of elements in the drawings may be exaggerated or reduced for convenience of explanation. In other words, since sizes and thicknesses of components in the drawings are arbitrarily illustrated for convenience of explanation, the following embodiments are not limited thereto.

In the following embodiments, "A and/or B" may include "A," "B," or "A and B." In addition, "at least one of A and B" or “ at least one selected from A and B” may include "A," "B," or "A and B."

In the following disclosure, it will be understood that when a wire is referred to as "extending in a first direction or a second direction", it can not only extend in a linear shape, but also can extend in the first direction or the second direction in a zigzag or curved shape.

In the following embodiments, "in a plan view" means that an object part is viewed from above (in other words, view in a thickness direction (z-axis direction) of the a display apparatus 1). In the following embodiments, "in a cross-sectional view" means that a cross-section obtained by vertically cutting an object part is viewed from the side. In the following embodiments, a first component "overlapping" a second component means that the first component is positioned above or below the second component.

The x-axis, the y-axis, and the z-axis are not limited to three axes on the orthogonal coordinates system, and may be interpreted in a broad sense including the same. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

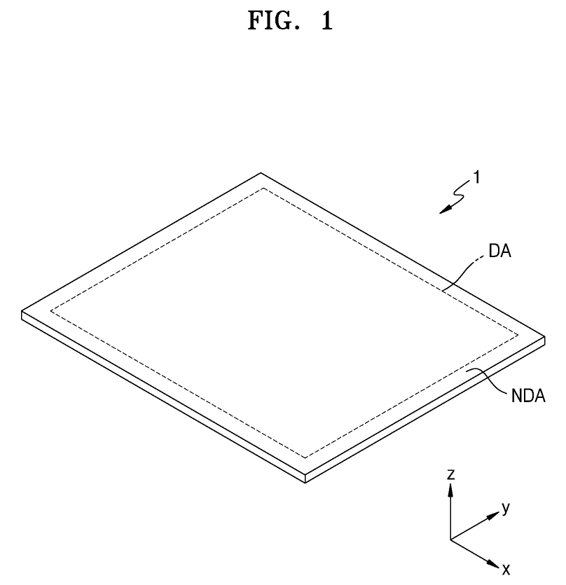

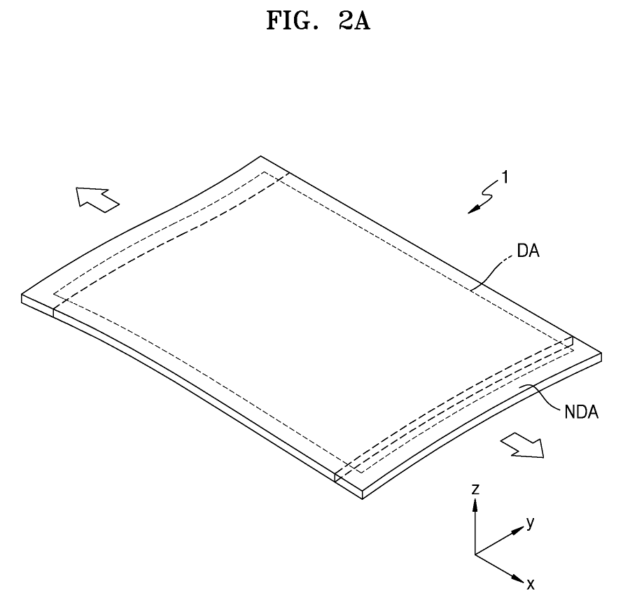

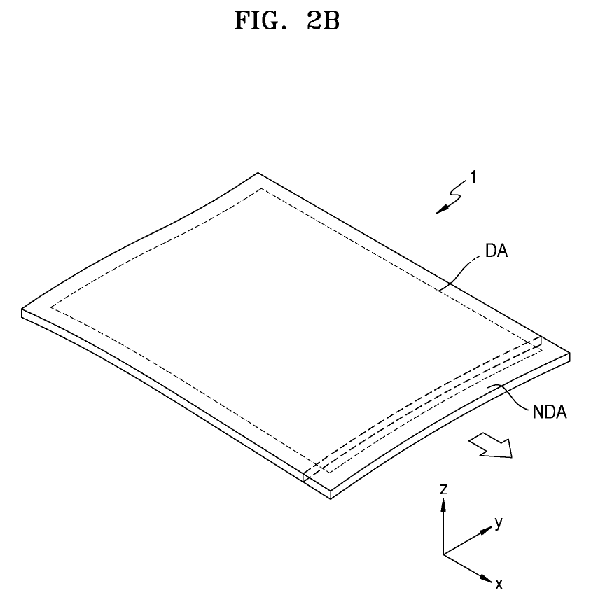

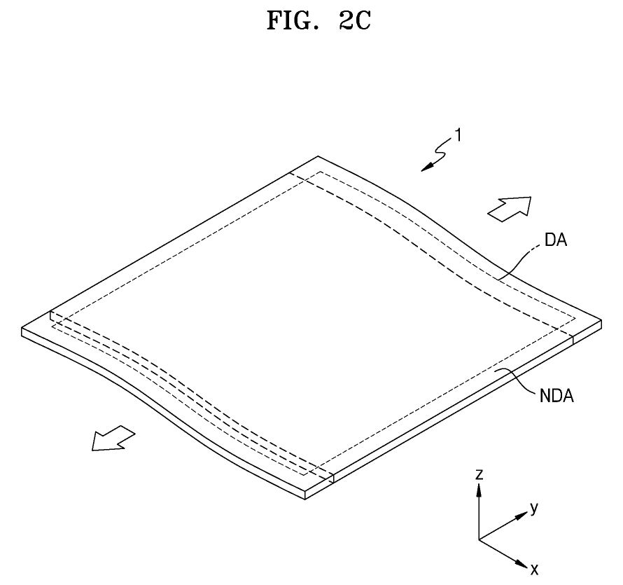

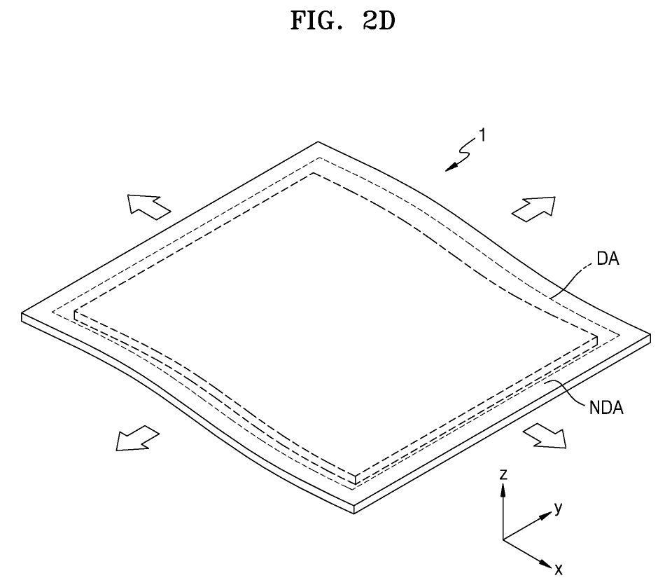

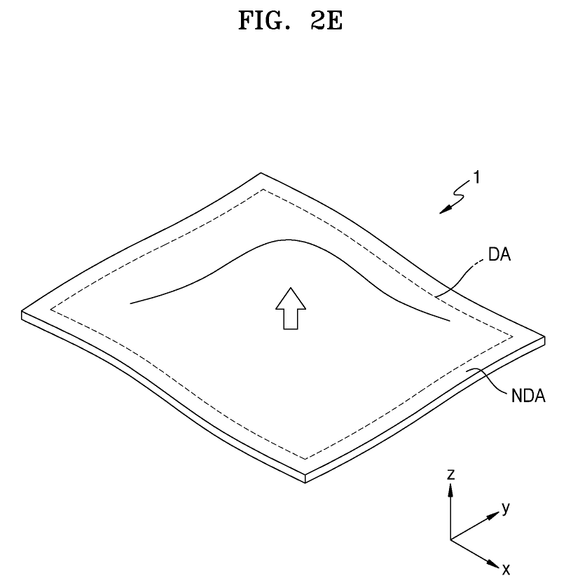

FIG. 1 is a perspective view schematically illustrating a display apparatus 1 according to an embodiment of the disclosure. FIGS. 2A and 2B are perspective views each illustrating a state in which the display apparatus 1 of FIG. 1 is stretched in a first direction. FIG. 2C is a perspective view illustrating a state in which the display apparatus 1 of FIG. 1 is stretched in a second direction. FIG. 2D is a perspective view illustrating a state in which the display apparatus 1 of FIG. 1 is stretched in the first direction and the second direction. FIG. 2E is a perspective view illustrating a state in which the display apparatus 1 of FIG. 1 is stretched in a third direction.

Referring to FIG. 1, the display apparatus 1 may include a display area DA and a non-display area NDA. The display area DA may include a plurality of pixels. The display apparatus 1 may provide an image by using light emitted by the plurality of pixels. The non-display area NDA may be disposed outside the display area DA. The non-display area NDA is an area in which the pixels are not disposed, and may entirely surround the display area DA.

The display apparatus 1 may be stretched or shrunk in various directions. The display apparatus 1 may be stretched in the first direction (e.g., an x direction and/or an -x direction) by an external force applied by an external object or a user. In an embodiment, as shown in FIGS. 2A and 2B, the display area DA and/or the non-display area NDA of the display apparatus 1 may be stretched in the first direction (e.g., the x direction and/or the -x direction). For example, as shown in FIG. 2A, the display apparatus 1 may be stretched in the x direction and the -x direction, or the display apparatus 1 may be stretched in the x direction in a state in which one side of the display apparatus 1 is fixed, as shown in FIG. 2B.

The display apparatus 1 may be stretched in the second direction (e.g., a y direction and/or a -y direction) by an external force applied by an external object or a user. In an embodiment, as shown in FIG. 2C, the display area DA and/or the non-display area NDA of the display apparatus 1 may be stretched in the y direction and the -y direction. In another embodiment, the display apparatus 1 may be stretched in the y direction or the -y direction in a state in which one side of the display apparatus 1 is fixed.

The display apparatus 1 may be stretched in a plurality of directions, for example, the first direction (e.g., the x direction and/or the -x direction) and the second direction (e.g., the y direction and/or the -y direction), by an external force applied by an external object or a part of a human's body. As shown in FIG. 2D, the display area DA and/or the non-display area NDA of the display apparatus 1 may be stretched in the ±x direction and the ±y direction.

The display apparatus 1 may be stretched in the third direction (e.g., the z direction or the -z direction) by an external force applied by an external object or a part of a human's body. In an embodiment, FIG. 2E shows that a portion of the display apparatus 1, for example, a partial area of the display area DA, protrudes in the z direction. In another embodiment, a portion of the display apparatus 1, for example, a partial area of the display area DA, may protrude in the -z direction (or may be depressed in the z direction).

FIGS. 2A to 2E show that the display apparatus 1 is stretched in the first direction, the second direction, and/or the third direction, but the disclosure is not limited thereto. In another embodiment, the display apparatus 1 may be variously modified into irregular shapes, such as having two or more axes and being bent or twisted.

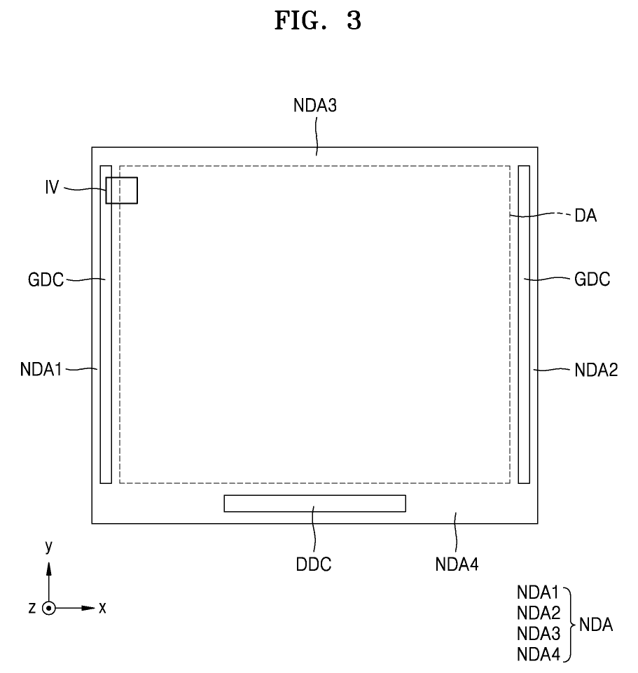

FIG. 3 is a schematic plan view of a display apparatus 1 according to an embodiment of the disclosure.

A plurality of pixels may be disposed in the display area DA of the display apparatus 1. Each of the plurality of pixels may include sub-pixels emitting light of different colors. A light-emitting element corresponding to each sub-pixel may be disposed in the display area DA. A circuit configured to provide electrical signals to the light-emitting elements disposed in the display area DA and transistors electrically connected to the light-emitting elements may be positioned in the non-display area NDA surrounding the display area DA. Gate driving circuits GDC may be disposed in a first non-display area NDA1 and a second non-display area NDA2, respectively, where the first non-display area NDA1 and the second non-display area NDA2 are disposed on opposite sides of the display area DA with the display area DA therebetween. A gate driving circuit GDC may include drivers configured to provide electrical signals to a gate electrode of each of the transistors electrically connected to the light-emitting elements. FIG. 3 shows that the gate driving circuit GDC is disposed in each of the first non-display area NDA1 and the second non-display area NDA2, but the disclosure is not limited thereto. In another embodiment, the gate driving circuit GDC may be disposed in any one of the first non-display area NDA1 and the second non-display area NDA2.

A data driving circuit DDC may be disposed in a third non-display area NDA3 and/or a fourth non-display area NDA4, which connects the first non-display area NDA1 to the second non-display area NDA2. In an embodiment, FIG. 3 shows that the data driving circuit DDC is disposed in the fourth non-display area NDA4. In another embodiment, the data driving circuit DDC may be disposed in each of the third non-display area NDA3 and the fourth non-display area NDA4.

FIG. 3 shows that the data driving circuit DDC is disposed in the fourth non-display area NDA4 of the display apparatus 1, but the disclosure is not limited thereto. In another embodiment, the display apparatus 1 may further include a flexible circuit board (not shown) electrically connected to a terminal portion (not shown) disposed in the fourth non-display area NDA4, and the data driving circuit DDC may be disposed on the flexible circuit board described above.

In some embodiments, an elongation of the non-display area NDA may be equal to or less than an elongation of the display area DA. In an embodiment, the non-display area NDA may have a different elongation for each area. For example, the first non-display area NDA1, the second non-display area NDA2, and the third non-display area NDA3 may have substantially the same elongation, but an elongation of the fourth non-display area NDA4 may be less than the elongation of each of the first non-display area NDA1, the second non-display area NDA2, and the third non-display area NDA3. In the disclosure, an elongation is a numerical value that represents a change in length (ΔL/L) by which the display apparatus 1 may be stretched without physical damage to the display apparatus 1 when an external force is applied to the display apparatus 1. Herein, ΔL is a change in length of a display apparatus, and L represents the initial length of the display apparatus.

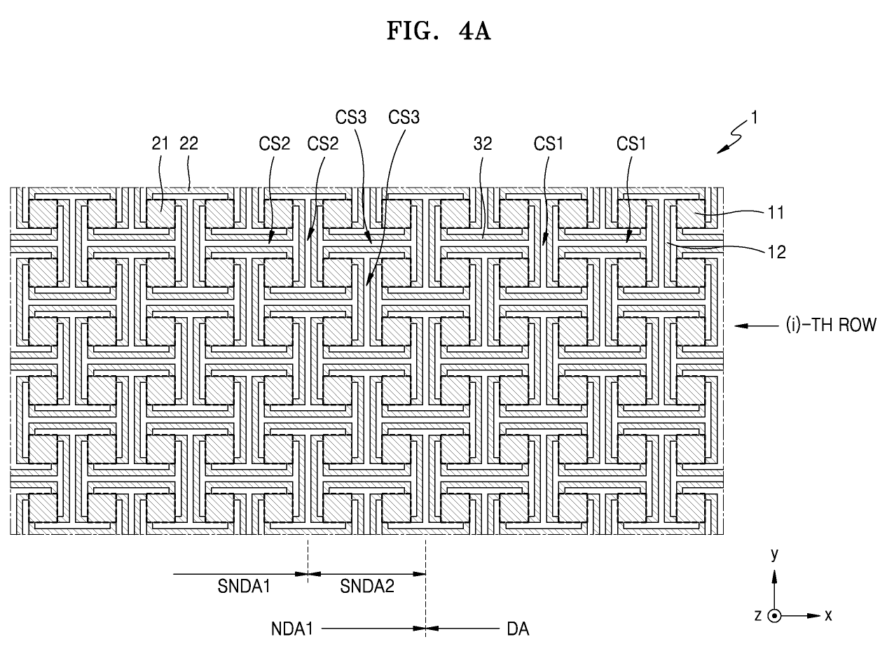

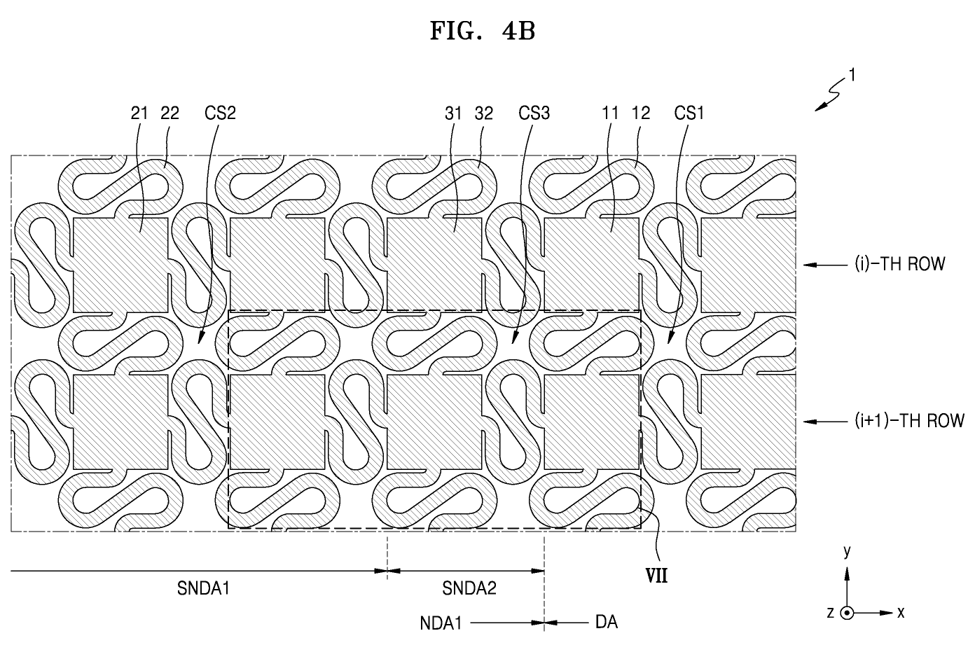

FIG. 4A is an enlarged plan view of a region IV of FIG. 3 as a portion of the display apparatus 1 according to an embodiment of the disclosure.

Referring to FIG. 4A, the display apparatus 1 may include, in the display area DA, first island portions 11 spaced apart from each other in the first direction (e.g., the x direction or the -x direction) and the second direction (e.g., the y direction or the-y direction), and first bridge portions 12 connecting adjacent first island portions 11 to each other.

Each first island portion 11 may be connected to a plurality of first bridge portions 12. For example, each first island portion 11 may be connected to four first bridge portions 12. Two first bridge portions 12 may be disposed on opposite sides of the first island portion 11 in the first direction (e.g., the x direction or the -x direction), respectively, and the remaining two first bridge portions 12 may be disposed on opposite sides of the first island portion 11 in the second direction (e.g., the y direction or the -y direction), respectively. In an embodiment, the four first bridge portions 12 may be connected to four sides of the first island portion 11, respectively. Each of the four first bridge portions 12 may be adjacent to each of corners of the first island portion 11.

The first bridge portions 12 may be spaced apart from each other by a first opening portion CS1 positioned between the first bridge portions 12. In an embodiment, a first opening portion CS1 having an approximately H shape and a first opening portion CS1 having an approximately I shape obtained by rotating the above described H shape by 90 degrees may be alternately and repeatedly arranged in each of the first direction (e.g., the x direction or the -x direction) and the second direction (e.g., the y direction or the -y direction). Both end portions of each first bridge portion 12 are connected to adjacent first island portions 11, respectively, but one side of each first bridge portion 12 may be spaced apart from one side of an adjacent first island portion 11 and/or one side of another first bridge portion 12 by the first opening portion CS1.

The display apparatus 1 may include second island portions 21 and second bridge portions 22, which are disposed in the non-display area, for example, the first non-display area NDA1. In an embodiment, the second island portions 21 and the second bridge portions 22 may have substantially the same shapes as the first island portions 11 and the first bridge portions 12, respectively.

The second island portions 21 may be spaced apart from each other in the first direction (e.g., the x direction or the -x direction) and the second direction (e.g., the y direction or the -y direction) in the non-display area, for example, the first non-display area NDA1. The second bridge portions 22 may be connected to adjacent second island portions 21, respectively. The second bridge portions 22 may be spaced apart from each other by a second opening portion CS2 positioned between the second bridge portions 22.

The second opening portion CS2 may have substantially the same shape as the first opening portion CS1. For example, a second opening portion CS2 having an approximately H shape and a second opening portion CS2 having an approximately I shape may be alternately and repeatedly arranged in the non-display area, for example, the first non-display area NDA1. Both end portions of each second bridge portion 22 are connected to adjacent second island portions 21, respectively, but one side of each second bridge portion 22 may be spaced apart from one side of an adjacent second island portion 21 and/or one side of another second bridge portion 22 by the second opening portion CS2.

Each second island portion 21 may be connected to four second bridge portions 22. Each second island portion 21 may include drivers of the gate driving circuit GDC (refer to FIG. 3) described above with reference to FIG. 3.

In an embodiment, the second island portions 21 of any one row disposed in the first non-display area NDA1 may correspond to the first island portions 11 of any one row arranged in the display area DA. For example, the second island portions 21 arranged in an (i)-th row in the first direction (e.g., the x direction or the -x direction) in the first non-display area NDA1 may correspond to the first island portions 11 arranged in the same row in the display area DA, for example, the (i)-th row (where i is a positive number greater than 0).

In an embodiment, any one second island portion 21 disposed in the first non-display area NDA1 may correspond to the first island portions 11 of a plurality of rows arranged in the display area DA. For example, any one second island portion 21 disposed in the first non-display area NDA1 may correspond to the first island portions 11 arranged in the (i)-th row and the first island portions 11 arranged in an (i+1)-th row in the display area DA (where i is a positive number greater than 0). In an embodiment, one second island portion 21 may correspond to two rows of first island portions 11, but the disclosure is not limited thereto. In another embodiment, any one second island portion 21 disposed in the first non-display area NDA1 may correspond to n rows of first island portions 11 disposed in the display area DA (where n is a positive number of 3 or more). In this case, it may be understood that in an embodiment, a size of the second island portion 21 may be smaller than a size of the first island portion 11.

The display apparatus 1 may include third island portions 31 and third bridge portions 32, which are disposed in a second sub-non-display area SNDA2 connecting the display area DA to a first sub-non-display-area SNDA1. The non-display area, for example, the first non-display area NDA1, may include the first sub-non-display-area SNDA1 in which the second island portions 21 and the second bridge portions 22 are disposed, and the second sub-non-display area SNDA2 including the third island portion 31 and the third bridge portions 32 and positioned between the first sub-non-display-area SNDA1 and the display area DA. A third island portion 31 may be substantially the same as the first island portion 11 and the second island portion 21. For example, the third island portion 31 may have substantially the same shape and size as the first island portion 11 and the second island portion 21. The third bridge portion 32 may be substantially the same as the first bridge portion 12 and the second bridge portion 22. For example, a width of the third bridge portion 32 may be equal to a width of the first bridge portion 12 and a width of the second bridge portion 22. Adjacent third island portions 31 are spaced apart from each other by a third opening portion CS3 but may be connected to each other by the third bridge portions 32. In addition, each third island portion 31 may include lines electrically connecting the first island portion 11 to the second island portion 21.

FIG. 4B is an enlarged plan view of the region IV of FIG. 3 as a portion of the display apparatus 1of FIG. 3, according to an embodiment of the disclosure.

Referring to FIG. 4B, the display apparatus 1 may include, in the display area DA, the first island portions 11 spaced apart from each other in the first direction (e.g., the x direction or the -x direction) and the second direction (e.g., the y direction or the-y direction), and the first bridge portions 12 connecting adjacent first island portions 11 to each other.

The first bridge portions 12 may be disposed to be spaced apart from each other by the first opening portion CS1 positioned between the first bridge portions 12. The first bridge portion 12 may have a serpentine shape. For example, as shown in FIG. 4B, the first bridge portion 12 may have an approximate shape of 'the letter S.'

Each first island portion 11 may be connected to a plurality of first bridge portions 12. For example, each first island portion 11 may be connected to four first bridge portions 12. Two first bridge portions 12 may be disposed on opposite sides of the first island portion 11 in the first direction (e.g., the x direction or the -x direction), respectively, and the remaining two first bridge portions 12 may be disposed on opposite sides of the first island portion 11 in the second direction (e.g., the y direction or the -y direction), respectively. The four first bridge portions 12 may be connected to four sides of the first island portion 11, respectively. Each of the four first bridge portions 12 may be connected to a central portion of each side of the first island portion 11.

The display apparatus 1 may include, in the non-display area, for example, the first non-display area NDA1 shown in FIG. 4B, the second island portions 21 spaced apart from each other in the first direction (e.g., the x direction or the -x direction) and the second direction (e.g., the y direction or the -y direction), and the second bridge portions 22 connecting adjacent second island portions 21 to each other.

The second bridge portions 22 may be disposed to be spaced apart from each other by the second opening portion CS2 positioned between the second bridge portions 22. The second bridge portion 22 may have a serpentine shape. For example, as shown in FIG. 4B, the second bridge portion 22 may have an approximate shape of 'the letter S.' In an embodiment, the size and/or width of the second bridge portion 22 may be the same as the size and/or width of the first bridge portion 12. In addition, the shape of the second bridge portion 22 may be the same as the shape of the first bridge portion 12.

Each second island portion 21 may be connected to a plurality of second bridge portions 22. Each second island portion 21 may be connected to four second bridge portions 22. Two second bridge portions 22 may be disposed on opposite sides of the second island portion 21 in the first direction (e.g., the x direction or the -x direction), respectively, and the remaining two second bridge portions 22 may be disposed on opposite sides of the second island portion 21 in the second direction (e.g., the y direction or the -y direction), respectively. In an embodiment, the four second bridge portions 22 may be connected to four sides of the second island portion 21, respectively. Each second bridge portion 22 may be connected to a central portion of each side of the second island portion 21.

In an embodiment, the second island portions 21 of any one row disposed in the first non-display area NDA1 may correspond to the first island portions 11 of any one row arranged in the display area DA. For example, the second island portions 21 arranged in the (i)-th row in the first direction (e.g., the x direction or the -x direction) in the first non-display area NDA1 may correspond to the first island portions 11 arranged in the same row in the display area DA, for example, the (i)-th row (where i is a positive number greater than 0).

In an embodiment, the second island portions 21 in any one row disposed in the first non-display area NDA1 may correspond to the first island portions 11 in a plurality of rows arranged in the display area DA. For example, the second island portions 21 of any one row disposed in the first non-display area NDA1 may correspond to the first island portions 11 arranged in the (i)-th row and the first island portions 11 arranged in the (i+1)-th row in the display area DA (where i is a positive number greater than 0). In another embodiment, the second island portions 21 of any one row may correspond to n rows of the first island portions 11 (where n is a positive number of 3 or more).

The non-display area, for example, the first non-display area NDA1, may include the first sub-non-display area SNDA1 in which the second island portions 21 and the second bridge portions 22 described above are disposed, and the second sub-non-display area SNDA2 between the first sub-non-display area SNDA1 and the display area DA. The third island portion 31 and the third bridge portions 32, which are configured to connect the display area DA to the first sub-non-display area SNDA1, may be disposed in the second sub-non-display area SNDA2.

The third bridge portions 32 may be disposed to be spaced apart from each other by the third opening portion CS3 positioned between the third bridge portions 32. A third bridge portion 32 may have a serpentine shape. For example, as shown in FIG. 4B, the third bridge portion 32 may have an approximate shape of 'the letter S.' In an embodiment, the size and/or width of the third bridge portion 32 may be the same as the size and/or width of the first bridge portion 12 and the size and/or width the second bridge portion 22. In addition, the shape of the third bridge portion 32 may be the same as the shape of the first bridge portion 12 and the shape of the second bridge portion 22.

Each third island portion 31 may be connected to a plurality of third bridge portions 32. Each third island portion 31 may be connected to four third bridge portions 32. Two third bridge portions 32 may be disposed on opposite sides of the third island portion 31 in the first direction (e.g., the x direction or the -x direction), respectively, and the remaining two third bridge portions 32 may be disposed on opposite sides of the third island portion 31 in the second direction (e.g., the y direction or the -y direction). In an embodiment, the four third bridge portions 32 may be connected to four sides of the third island portion 31, respectively. Each third bridge portion 32 may be connected to a central portion of each side of the third island portion 31.

Hereinafter, for convenience of explanation, a case in which the display apparatus 1 has a structure as shown in FIG. 4B is mainly described.

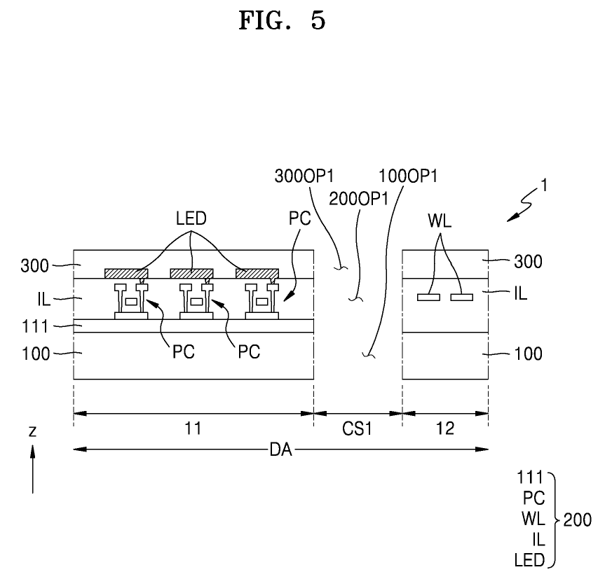

FIG. 5 is a schematic cross-sectional view of the first island portion 11 and the first bridge portion 12, which are disposed in the display area DA of the display apparatus 1 according to an embodiment of the disclosure.

Referring to FIG. 5, the first island portion 11 and the first bridge portion 12, which are disposed in the display area DA, may be spaced apart from each other with the first opening portion CS1 therebetween. The first island portion 11 may include light-emitting elements LED and a circuit electrically connected to the light-emitting elements LED and configured to drive the light-emitting elements LED, for example, a pixel driving circuit unit PC, and the first bridge portion 12 may include a line WL electrically connected to pixel driving circuit units PC disposed in adjacent first island portions 11, respectively.

When looking at the first island portion 11, a buffer layer 111 including an inorganic insulating material may be disposed on a substrate 100, and the pixel driving circuit unit PC may be disposed on the buffer layer 111. An insulating layer IL including an inorganic insulating material and/or an organic insulating material may be disposed between the pixel driving circuit unit PC and the light-emitting element LED. The light-emitting element LED may be disposed on the insulating layer IL and may be electrically connected to a corresponding pixel driving circuit unit PC. The light-emitting elements LED may emit light of different colors or the same color. In an embodiment, the light-emitting elements LED may emit red, green, and blue light, respectively. In some embodiments, the light-emitting elements LED may emit white light. In another embodiment, the light-emitting elements LED may emit red, green, blue, and white light, respectively.

The substrate 100 may include a polymer resin, such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may be a single layer including the polymer resin described above. In another embodiment, the substrate 100 may have a multi-layered structure including a base layer including the polymer resin described above, and a barrier layer including an inorganic insulating material. The substrate 100 including the polymer resin may be flexible, rollable, or bendable.

In an embodiment, FIG. 5 shows three pixel driving circuit units PC disposed in each first island portion 11 and three light-emitting elements LED are connected to the pixel driving circuit units PC, respectively, but the disclosure is not limited thereto. In another embodiment, the number of pixel driving circuits units PC and the number of light-emitting elements LED, which are disposed in the first island portion 11, may be one, two, or four or more.

An encapsulation layer 300 may be disposed on the light-emitting element LED and may protect the light-emitting element LED from external force and/or moisture penetration. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In some embodiments, the encapsulation layer 300 may include urethane epoxy acrylate. The encapsulation layer 300 may include a photosensitive material, for example, a material such as photoresist.

When looking at the first bridge portion 12, the insulating layer IL including an organic insulating material may be disposed on the substrate 100. When the display apparatus 1 is stretched, the first bridge portion 12, which is relatively deformed, may not include a layer including an inorganic insulating material that is prone to cracks, unlike the first island portion 11.

In an embodiment, the substrate 100 corresponding to the first bridge portion 12 may have the same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a stacked structure different from that of the substrate 100 corresponding to the first island portion 11. In some embodiments, the substrate 100 corresponding to the first island portion 11 may have a multi-layered structure including a base layer including a polymer resin and a barrier layer including an inorganic insulating material, and the substrate 100 corresponding to the first bridge portion 12 may have a structure of a polymer resin layer without a layer including an inorganic insulating material.

As described above, lines WL of the first bridge portion 12 may be signal lines (e.g., gate lines, data lines, or the like) for providing electrical signals to transistors included in the pixel driving circuit unit PC of the first island portion 11, or may be voltage lines (e.g., driving voltage lines, initialization voltage lines, or the like) for providing voltages. The encapsulation layer 300 may also be disposed in the first bridge portion 12. In another embodiment, the encapsulation layer 300 may not be present in the first bridge portion 12.

Referring to FIGS. 4A, 4B, and 5, the substrate 100 corresponding to the first island portion 11 and the substrate 100 corresponding to the first bridge portion 12 may be connected to each other. In other words, the plan views previously shown in FIGS. 4A and 4B may be substantially the same as the plan view of the substrate 100 of FIG. 5. That is, the substrate 100 may include an area corresponding to the first island portion 11, an area corresponding to the first bridge portion 12, and an opening 100OP1 having the same shape as the first opening portion CS1.

Similarly, the encapsulation layer 300 corresponding to the first island portion 11 and the encapsulation layer 300 corresponding to the first bridge portion 12 may be connected to each other. For example, the plan views previously shown in FIGS. 4A and 4B may be substantially the same as the plan view of the encapsulation layer 300. In other words, the encapsulation layer 300 may include an area corresponding to the first island portion 11, an area corresponding to the first bridge portion 12, and an opening 300OP1 having the same shape as the first opening portion CS1.

A circuit-light-emitting element layer 200 between the substrate 100 and the encapsulation layer 300 may include the buffer layer 111, the pixel driving circuit unit PC, the line WL, the insulating layer IL, and the light-emitting element LED. Similar to the substrate 100, the plan views previously shown in FIGS. 4A and 4B may be substantially the same as the plan view of the circuit-light-emitting element layer 200. In other words, the circuit-light-emitting element layer 200 may include an opening 200OP1 having the same shape as the first opening portion CS1.

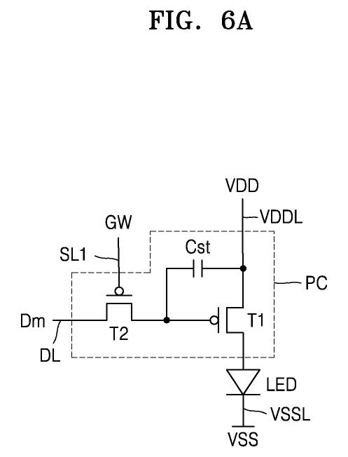

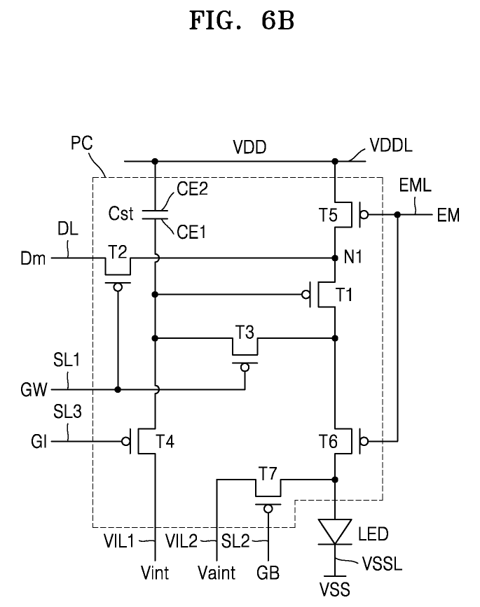

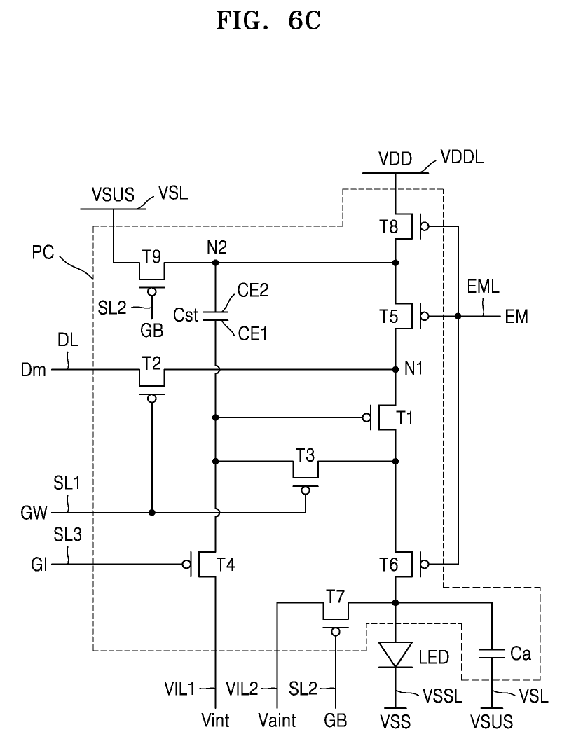

FIGS. 6A to 6C are equivalent circuit diagrams each illustrating a sub-pixel of the display apparatus 1 according to an embodiment of the disclosure.

Referring to FIG. 6A, a light-emitting element LED corresponding to the sub-pixel may be electrically connected to a pixel driving circuit unit PC, and the pixel driving circuit unit PC may include a first transistor T1, a second transistor T2, and a storage capacitor Cst. The pixel driving circuit unit PC may be electrically connected to signal lines and voltage lines. The signal lines may include a gate line, such as a first scan line SL1, and a data line DL, and the voltage lines may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may be configured to transmit, to the first transistor T1, a data signal Dm input from the data line DL according to the first scan signal GW input from the first scan line SL1.

The storage capacitor Cst may be electrically connected to the second transistor T2 and the first voltage line VDDL, and may store a voltage corresponding to the difference between a voltage received from the second transistor T2 and a first power voltage VDD supplied by the first voltage line VDDL.

The first transistor T1 is a driving transistor, which may control a driving current flowing through the light-emitting element LED. The first transistor T1 may be connected to the first voltage line VDDL and the storage capacitor Cst. The first transistor T1 may control the driving current flowing through the light-emitting element LED from the first voltage line VDDL in accordance to a voltage value stored in the storage capacitor Cst. The light-emitting element LED may emit light having a certain brightness according to the driving current. A first electrode of the light-emitting element LED may be electrically connected to the first transistor T1, and a second electrode thereof may be electrically connected to a second voltage line VSSL providing a second power voltage VSS.

Although FIG. 6A illustrates that the pixel driving circuit unit PC includes two transistors and one storage capacitor, in another embodiment, the pixel driving circuit unit PC may include three or more transistors.

Referring to FIG. 6B, the pixel driving circuit unit PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit unit PC is electrically connected to signal lines and voltage lines. The signal lines may include gate lines, such as the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may be configured to transmit the first power voltage VDD to the first transistor T1. The first initialization voltage line VIL1 may be configured to transmit, to the pixel driving circuit unit PC, a first initialization voltage Vint initializing the first transistor T1. The second initialization voltage line VIL2 may be configured to transmit, to the pixel driving circuit unit PC, a second initialization voltage Vaint initializing a first electrode of the light-emitting element LED.

The first transistor T1 may be electrically connected to the first voltage line VDDL via the fifth transistor T5 and may be electrically connected to the light-emitting element LED via the sixth transistor T6. The first transistor T1 serves as a driving transistor and receives the data signal Dm in response to a switching operation of the second transistor T2 to supply a driving current to the light-emitting element LED.

The second transistor T2 is a data write transistor, which is electrically connected to the first scan line SL1 and the data line DL. The second transistor T2 is electrically connected to the first voltage line VDDL via the fifth transistor T5. The second transistor T2 is turned on in response to the first scan signal GW received through the first scan line SL1 and performs a switching operation of providing the data signal Dm provided with the data line DL to a first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1.

The fourth transistor T4 is a first initialization transistor, which is electrically connected to the third scan line SL3 and the first initialization voltage line VIL1. The fourth transistor T4 is turned on in response to a third scan signal GI received through the third scan line SL3 to provide the first initialization voltage Vint from the first initialization voltage line VIL1 to a gate electrode of the first transistor T1 to initialize a voltage of the gate electrode of the first transistor T1. The third scan signal GI may correspond to a first scan signal of another pixel driving circuit unit disposed in a previous row of the corresponding pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML and are simultaneously turned on in response to an emission control signal EM received through the emission control line EML to form a current path so that a driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 may be turned on in response to a second scan signal GB received through the second scan line SL2 to provide the second initialization voltage Vaint from the second initialization voltage line VIL2 to the first electrode of the light-emitting element LED to initialize the first electrode of the light-emitting element LED.

The storage capacitor Cst includes the first electrode CE1 and the second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to the difference between voltages of opposite ends of the first voltage line VDDL and the gate electrode of the first transistor T1.

Referring to FIG. 6C, the pixel driving circuit unit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit unit PC is electrically connected to signal lines and voltage lines. The signal lines may include gate lines, such as the first scan line SL1, the second scan line SL2, the third scan line SL3, and the emission control line EML, and the data line DL. The voltage lines may include the first and second initialization voltage lines VIL1 and VIL2, a maintenance voltage line VSL, and the first voltage line VDDL.

The first voltage line VDDL may be configured to transmit the first power voltage VDD to the first transistor T1. The first initialization voltage line VIL1 may be configured to transmit, to the pixel driving circuit unit PC, the first initialization voltage Vint initializing the first transistor T1. The second initialization voltage line VIL2 may be configured to transmit, to the pixel driving circuit unit PC, the second initialization voltage Vaint initializing the first electrode of the light-emitting element LED. The maintenance voltage line VSL may provide a maintenance voltage VSUS to a second node N2, for example,

the second electrode CE2 of the storage capacitor Cst, during an initialization section and a data write section.

The first transistor T1 may be electrically connected to the first voltage line VDDL via the fifth transistor T5 and the eighth transistor T8, and may be electrically connected to the light-emitting element LED via the sixth transistor T6. The first transistor T1 may serve as a driving transistor and receive the data signal Dm in response to a switching operation of the second transistor T2 to supply a driving current to the light-emitting element LED.

The second transistor T2 is electrically connected to the first scan line SL1 and the data line DL, and is electrically connected to the first voltage line VDDL via the fifth transistor T5 and the eighth transistor T8. The second transistor T2 is turned on in response to the first scan signal GW received through the first scan line SL1 and performs a switching operation of providing the data signal Dm provided through the data line DL to the first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1, thereby compensating for a threshold voltage of the first transistor T1.

The fourth transistor T4 is electrically connected to the third scan line SL3 and the first initialization voltage line VIL1 and turned on in response to the third scan signal GI received through the third scan line SL3 to provide the first initialization voltage Vint from the first initialization voltage line VIL1 to the gate electrode of the first transistor T1 to initialize a voltage of the gate electrode of the first transistor T1. The third scan signal GI may correspond to a first scan signal of another pixel driving circuit unit disposed in a previous row of the corresponding pixel driving circuit unit PC.

The fifth transistor T5, the sixth transistor T6, and the eighth transistor T8 are electrically connected to the emission control line EML and simultaneously turned on in response to the emission control signal EM received through the emission control line EML to form a current path so that the driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 is turned on in response to the second scan signal GB received through the second scan line SL2 to provide the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the maintenance voltage line VSL. The ninth transistor T9 may be turned on in response to the second scan signal GB received through the second scan line SL2 to provide the maintenance voltage VSUS to the second node N2, for example, the second electrode CE2 of the storage capacitor Cst, during an initialization section and a data write section.

Each of the eighth transistor T8 and the ninth transistor T9 may be electrically connected to the second node N2, for example, the second electrode CE2 of the storage capacitor Cst. In some embodiments, the eighth transistor T8 may be turned off and the ninth transistor T9 may be turned on during the initialization section and the data write section, and the eighth transistor T8 may be turned on and the ninth transistor T9 may be turned off during an emission section. Because the maintenance voltage VSUS is transmitted to the second node N2 during the initialization section and the data write section, the brightness uniformity (for example, long-range uniformity (LRU)) of a display apparatus according to a voltage drop of the first voltage line VDDL may be improved.

The storage capacitor Cst may include the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to the voltage difference between the first electrode of the light-emitting element LED and the maintenance voltage line VSL while the seventh transistor T7 and the ninth transistor T9 are turned on, so that a problem in which black brightness increases when the sixth transistor T6 is turned off may be prevented.

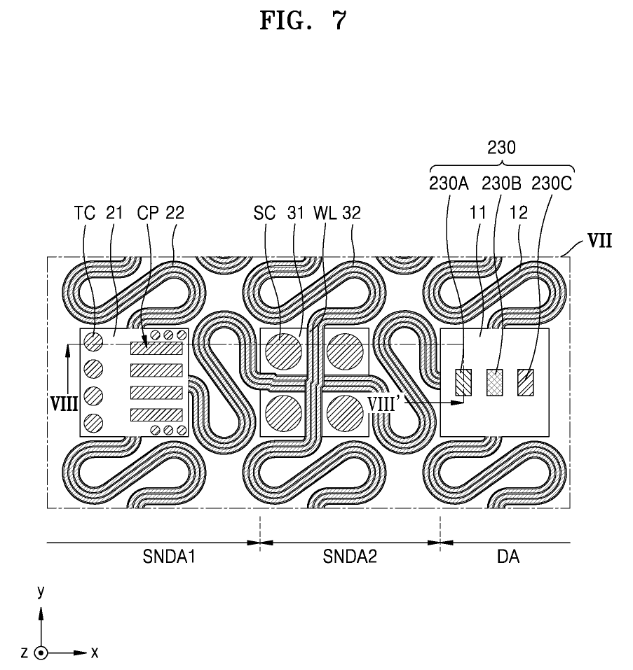

FIG. 7 is an enlarged plan view of a region VII of FIG. 4B as a portion of the display apparatus of FIG. 4B, according to an embodiment of the disclosure.

Referring to FIG. 7B, the first island portion 11 may be disposed in the display area DA, as described above. Light-emitting elements may be disposed in the first island portion 11. In an embodiment, FIG. 7 illustrates that the light-emitting elements disposed in the first island portion 11 includes first to third light-emitting diodes 230A, 230B, and 230C, which emit light of different colors. For example, one of the first to third light-emitting diodes 230A, 230B, and 230C may emit red light, another may emit green light, and the remaining one may emit blue light.

Each of the light-emitting diodes 230 may be electrically connected to the pixel driving circuit unit PC (refer to FIG. 5), and may also be electrically connected to the second voltage line VSSL, which is a common power line.

The second island portion 21 may be disposed in the non-display area NDA, for example, the first sub-non-display area SNDA1. A circuit unit CP may be disposed in the second island portion 21. In an embodiment, the circuit unit CP may be a driver of the gate driving circuit GDC (refer to FIG. 3), as described above.

The third island portion 31 may be disposed in the non-display area NDA, for example, the second sub-non-display area SNDA2. That is, the third island portion 31 may be disposed between the first island portion 11 and the second island portion 21. The line WL electrically connecting the first island portion 11 to the second island portion 21 may be disposed in the third island portion 31. In an embodiment, the lines WL may be signal lines (e.g., gate lines, data lines, or the like) for providing electrical signals or voltage lines (e.g., driving voltage lines, initialization voltage lines, or the like) for providing voltages to a transistor included in the pixel driving circuit unit PC (refer to FIG. 5). In an embodiment, the line WL may be electrically connected to the third island portion 31 from the second island portion 21 through the second bridge portion 22, and may be connected to the first island portion 11 through the third bridge portion 32 across the third island portion 31.

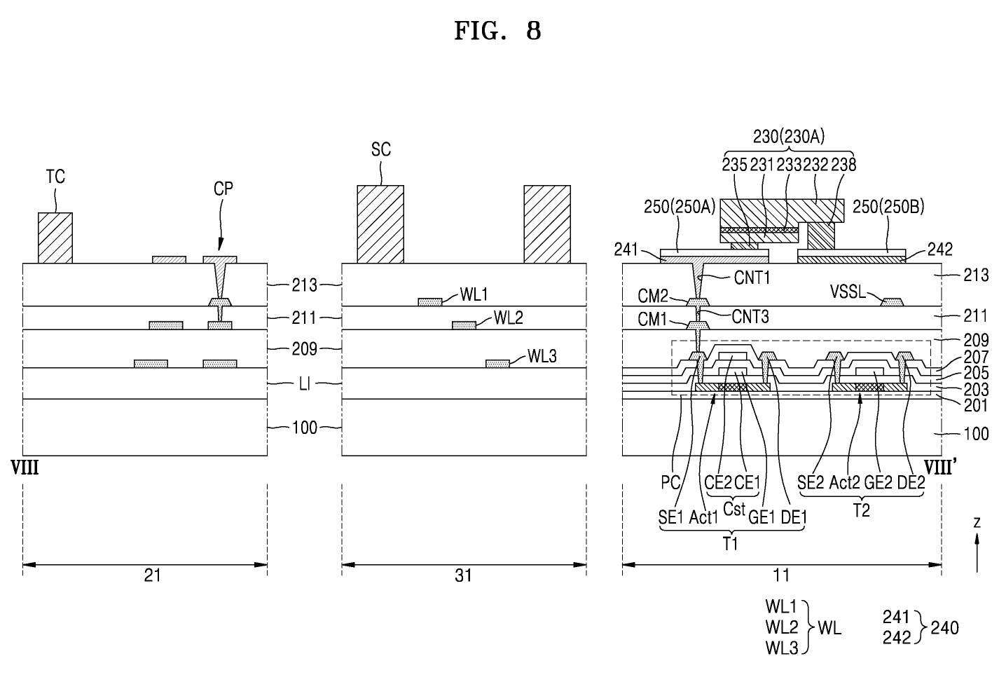

FIG. 8 is a cross-sectional view schematically illustrating a display apparatus according to an embodiment of the disclosure, corresponding to a cross-section taken along line VIII-VIII' of FIG. 7. In FIG. 8, for convenience of explanation, bridge portions are omitted, and island portions are mainly illustrated.

Referring to FIGS. 7 and 8, the pixel driving circuit unit PC and a light-emitting diode 230, which is a light-emitting element electrically connected to the pixel driving circuit unit PC, are disposed on the substrate 100 of the first island portion 11. FIG. 8 illustrates that the light-emitting diode 230 is the first light-emitting diode 230A as an embodiment, but the disclosure is not limited thereto. The structure of the second light-emitting diode 230B and the pixel driving circuit unit PC and the structure of the third light-emitting diode 230C and the pixel driving circuit unit PC are identical to the structure as shown in FIG. 8.

The substrate 100 may include a polymer resin, such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may be a single layer including the polymer resin described above. In another embodiment, the substrate 100 may have a multi-layered structure including a base layer including the polymer resin described above, and a barrier layer including an inorganic insulating material. The substrate 100 including the polymer resin may be flexible, rollable, or bendable.

The pixel driving circuit unit PC may include transistors and the storage capacitor Cst, which are described above with reference to FIGS. 6A to 6C. In this regard, FIG. 8 shows the first transistor T1 and the second transistor T2 among the transistors of the pixel driving circuit unit PC.

A buffer layer 201 may be disposed between the substrate 100 and the pixel driving circuit unit PC and prevent penetration of foreign materials into the transistors. The buffer layer 201 may include an inorganic insulating material, such as silicon oxide, silicon nitride, and silicon oxynitride, and may include a single layer or a multi-layer, each including the inorganic insulating material stated above.

The first transistor T1 may include a first semiconductor layer Act1 and a first gate electrode GE1. A source area and a drain area of the first semiconductor layer Act1 may be electrically connected to a first source electrode SE1 and/or a first drain electrode DE1, respectively. The second transistor T2 may include a second semiconductor layer Act2 and a second gate electrode GE2. A source area and a drain area of the second semiconductor layer Act2 may be electrically connected to a second source electrode SE2 and/or a second drain electrode DE2, respectively.

FIG. 8 illustrates a top-gate type in which the first and second gate electrodes GE1 and GE2 are disposed on the first and second semiconductor layers Act1 and Act2 with a gate insulating layer 203 therebetween, respectively, but according to another embodiment, the first and second transistors T1 and T2 may each be a bottom-gate type.

In an embodiment, each of the first and second semiconductor layers Act1 and Act2 may include polysilicon. In an embodiment, each of the first and second semiconductor layers Act1 and Act2 may include amorphous silicon, an oxide semiconductor, an organic semiconductor, or the like. Each of the first and second gate electrodes GE1 and GE2 may include a low-resistance metal material. Each of the first and second gate electrodes GE1 and GE2 may include a conductive material including molybdenum (Mo), aluminum (Al), copper (Cu), titanium (Ti), or the like, and may include a multi-layer or a single layer, each including the material stated above.

The gate insulating layer 203 may include an inorganic insulating material, such as silicon oxide, silicon nitride, and silicon oxynitride, and may include a single layer or a multi-layer, each including the material stated above.

The storage capacitor Cst may include the first electrode CE1 and the second electrode CE2, which overlap each other with a first interlayer-insulating layer 205 therebetween in a plan view. In an embodiment, the storage capacitor Cst may overlap the first transistor T1. In this regard, FIG. 8 shows that the first gate electrode GE1 of the first transistor T1 is the first electrode CE1 of the storage capacitor Cst. In another embodiment, the storage capacitor Cst may not overlap the first transistor T1 in a plan view. The storage capacitor Cst may be covered by a second interlayer-insulating layer 207. The second electrode CE2 of the storage capacitor Cst may include a conductive material including Mo, Al, Cu, Ti, or the like, and may include a multi-layer or a single layer, each including the above-mentioned material.

The first and second source electrodes SE1 and SE2 and the first and second drain electrodes DE1 and DE2 may be disposed on the same layer, for example, on the second interlayer-insulating layer 207, and may include the same material. The first and second source electrodes SE1 and SE2 and the first and second drain electrodes DE1 and DE2 may each include a conductive material including Mo, Al, Cu, Ti, or the like, and may include a multi-layer or a single layer, each including the above material.

Each of the first interlayer-insulating layer 205 and the second interlayer-insulating layer 207 may include an inorganic insulating material, such as silicon oxide, silicon nitride, and silicon oxynitride, and may include a single layer or a multi-layer, each including the inorganic insulating material stated above. The first and second transistors T1 and T2 and the storage capacitor Cst may be covered with a first organic insulating layer 209.

A second organic insulating layer 211 and a third organic insulating layer 213 may be sequentially disposed on the first organic insulating layer 209. Each of the first organic insulating layer 209, the second organic insulating layer 211, and the third organic insulating layer 213 may include an organic insulating material. The organic insulating material may include a general commercial polymer such as poly(methyl methacrylate) (PMMA) or polystyrene (PS), a polymer derivative having a phenol group, an acrylic polymer, an imide polymer, an aryl ether polymer, an amide polymer, a fluorine polymer, a p-xylene polymer, a vinyl alcohol polymer, and a mixture thereof.

The second voltage line VSSL may be disposed on the second organic insulating layer 211. Although not illustrated in the drawing, the first voltage line VDDL (refer to FIGS. 6A to 6C) may be disposed on the first organic insulating layer 209 or the second organic insulating layer 211.

A first electrode pad 241 may be disposed on the third organic insulating layer 213. The first electrode pad 241 may be connected to a second contact metal CM2 through a first contact hole CNT1, and the second contact metal CM2 may be connected to a first contact metal CM1 through a third contact hole CNT3. FIG. 8 illustrates that the first electrode pad 241 is electrically connected to the first transistor T1 through the first and second contact metals CM1 and CM2, but the disclosure is not limited thereto. As described above with reference to FIGS. 6A to 6C, the pixel driving circuit unit PC may further include the sixth transistor T6 (refer to FIGS. 6B and 6C), and in this case, the first electrode pad 241 may be electrically connected to the sixth transistor T6 (refer to FIGS. 6B and 6C) through the first and second contact metals CM1 and CM2. The sixth transistor T6 (refer to FIGS. 6B and 6C) may have a structure that is substantially the same as the structure of the first transistor T1.

A second electrode pad 242 may be disposed on the same layer as the first electrode pad 241, for example, on the third organic insulating layer 213. The second electrode pad 242 may be electrically connected to the second voltage line VSSL through a second contact hole (not shown).

The light-emitting diode 230 may be an inorganic light-emitting diode. For example, the light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232.

The first semiconductor layer 231 may include, for example, a p-type semiconductor layer. The p-type semiconductor layer is a semiconductor material with a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, or the like, and may be doped with a p-type dopant such as Mg, Zn, Ca, Sr, Ba, or the like.

The second semiconductor layer 232 may include, for example, an n-type semiconductor layer. The n-type semiconductor layer is a semiconductor material having a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, or the like, and may be doped with an n-type dopant such as Si, Ge, Sn, or the like.

The intermediate layer 233 is a region where electrons and holes recombine. As the electrons and holes recombine, the intermediate layer 233 may transition to a low energy level and generate light having a corresponding wavelength. For example, the intermediate layer 233 may be formed by including a semiconductor material having a composition formula of InₓAl_{y}Ga_{1-x-y}N (0≤x≤1, 0≤y≤1, 0≤x+y≤1), and may be formed as a single-quantum well structure or a multi-quantum well (MQW) structure. In addition, the intermediate layer 233 may also include a quantum wire structure or a quantum dot structure.

FIG. 8 illustrates that the first semiconductor layer 231 includes a p-type semiconductor layer, and the second semiconductor layer 232 includes an n-type semiconductor layer, but the disclosure is not limited thereto. In another embodiment, the first semiconductor layer 231 may include an n-type semiconductor layer, and the second semiconductor layer 232 may include a p-type semiconductor layer.

The first electrode 235 and the second electrode 238 of the light-emitting diode 230 may be electrically connected to the first electrode pad 241 and the second electrode pad 242 through a bump metal 250, respectively.

As the light-emitting diode 230 is formed by disposing the bump metal 250 on each of the first electrode pad 241 and the second electrode pad 242 and then disposing the light-emitting diode 230 by applying certain heat and certain pressure, the first electrode pad 241 and the second electrode pad 242 may be electrically connected to the light-emitting diode 230. For example, the light-emitting diode 230 may be electrically connected to the first electrode pad 241 through a first bump metal 250A between the light-emitting diode 230 and the first electrode pad 241. The light-emitting diode 230 may be electrically connected to the second electrode pad 242 through a second bump metal 250B between the light-emitting diode 230 and the second electrode pad 242.

The circuit unit CP may be disposed above the substrate 100 of the second island portion 21. As described above, the substrate 100 of the second island portion 21 may be connected to the substrate 100 of the first island portion 11 and the substrate 100 of the third island portion 31 and formed as an integral body.

A lower insulating layer LI may be disposed on the substrate 100. In an embodiment, the lower insulating layer LI may include an organic insulating material, such as polyimide, or an inorganic insulating material, such as silicon oxide, silicon nitride, and silicon oxynitride. In addition, the lower insulating layer LI may be a single layer or a multi-layer. In an embodiment, the lower insulating layer LI may have a thickness corresponding to the inorganic insulating layers 201, 203, 205, and 207. In some embodiments, the lower insulating layer LI may also be omitted.

The first organic insulating layer 209 may be disposed on the lower insulating layer LI, and the second organic insulating layer 211 and the third organic insulating layer 213 may be sequentially disposed on the first organic insulating layer 209. Each of the first organic insulating layer 209, the second organic insulating layer 211, and the third organic insulating layer 213 may include an organic insulating material. The organic insulating material may include a general commercial polymer such as PMMA or PS, a polymer derivative having a phenol group, an acrylic polymer, an imide polymer, an aryl ether polymer, an amide polymer, a fluorine polymer, a p-xylene polymer, a vinyl alcohol polymer, and a mixture thereof.

The circuit unit CP may be disposed between insulating layers. For example, the circuit unit CP may include a plurality of circuit patterns, some of the circuit patterns may be disposed on the third organic insulating layer 213, some other circuit patterns may be disposed between the third organic insulating layer 213 and the second organic insulating layer 211, some other circuit patterns may be disposed between the second organic insulating layer 211 and the first organic insulating layer 209, and some other circuit patterns may be disposed between the first organic insulating layer 209 and the lower insulating layer LI. At least some of the circuit patterns may be connected to each other through contact holes.

The lines WL may be disposed above the substrate 100 of the third island portion 31. As described above, the substrate 100 of the third island portion 31 may be connected to the substrate 100 of the first island portion 11 and the substrate 100 of the second island portion 21 and formed as an integral body.

The lower insulating layer LI may be disposed on the substrate 100. In an embodiment, the lower insulating layer LI may include an organic insulating material, such as polyimide, or an inorganic insulating material, such as silicon oxide, silicon nitride, and silicon oxynitride. In addition, the lower insulating layer LI may be a single layer or a multi-layer. In an embodiment, the lower insulating layer LI may have a thickness corresponding to the inorganic insulating layers 201, 203, 205, and 207. In some embodiments, the lower insulating layer LI may also be omitted.

The first organic insulating layer 209 may be disposed on the lower insulating layer LI, and the second organic insulating layer 211 and the third organic insulating layer 213 may be sequentially disposed on the first organic insulating layer 209. Each of the first organic insulating layer 209, the second organic insulating layer 211, and the third organic insulating layer 213 may include an organic insulating material. The organic insulating material may include a general commercial polymer such as PMMA or PS, a polymer derivative having a phenol group, an acrylic polymer, an imide polymer, an aryl ether polymer, an amide polymer, a fluorine polymer, a p-xylene polymer, a vinyl alcohol polymer, and a mixture thereof.

A plurality of lines WL, for example, first to third lines WL1, WL2, and WL3, may be disposed on different layers. For example, the first line WL1 may be disposed between the third organic insulating layer 213 and the second organic insulating layer 211, the second line WL2 may be disposed on the second organic insulating layer 211 and the first organic insulating layer 209, and the third line WL3 may be disposed between the first organic insulating layer 209 and the lower insulating layer LI. However, the disclosure is not limited thereto, and in another embodiment, at least some of the first to third lines WL1, WL2, and WL3 may be disposed on the same layer.

A support column SC may be disposed on an upper portion (e.g., upper surface) of the third island portion 31. For example, the support column SC may be disposed on an upper portion of the third organic insulating layer 213 of the third island portion 31. In an embodiment, a height of the support column SC may be greater than a height of the light-emitting diode 230. That is, a height from an upper surface of the third organic insulating layer 213 to an upper surface of the support column SC may be greater than a height from the upper surface of the third organic insulating layer 213 to an upper surface of the light-emitting diode 230. In addition, a height from a lower surface of the third island portion 31 to the upper surface of the support column SC may be greater than a height from a lower surface of the first island portion 11 to the upper surface of the light-emitting diode 230. In an embodiment, the support column SC may include an organic material.

In an embodiment, such a support column SC may be disposed not to overlap the lines WL disposed in the third island portion 31 in a plan view. For example, the third island portion 31 may have an approximately rectangular shape, and the lines WL may be disposed to extend across the third island portion 31 in the first direction (x direction) and the second direction (y direction) intersecting the first direction. The lines WL may be disposed in an approximately '+' shape by crossing a central portion of the third island portion 31.

In this case, the support column SC may be disposed not to overlap the lines WL in a plan view. For example, the support column SC may include a plurality of support columns, for example four support columns. Four support columns SC may be disposed adjacent to each of four corners of the third island portion 31.

As described above, the light-emitting diode 230 may be disposed in the first island portion 11 and then pressed with a certain pressure. For example, the upper surface of the light-emitting diode 230 may be pressed by using a pressing plate so that the light-emitting diode 230 may be connected to an electrode pad 240. In this case, the pressing plate may also cover the non-display area NDA outside the display area DA, as well as the display area DA. Accordingly, when pressing the light-emitting diode 230, the pressing plate may press the non-display area NDA, for example, upper portions of the second island portion 21 and the third island portion 31, which may cause damage. In this case, in particular, the circuit unit CP of the second island portion 21 may be damaged.

According to embodiments of the disclosure, the support column SC may support the pressing plate in the non-display area NDA. As the third island portion 31 is disposed adjacent to the second island portion 21, the circuit unit CP of the third island portion 31 may be protected by supporting the pressing plate with the support column SC disposed in the second island portion 21. In addition, as the support column SC is disposed not to overlap the lines WL in a plan view, pressure damage to the lines WL caused by being disposed on a lower portion of the support column SC, which receives a pressing force of the pressing plate, may be effectively prevented.

In addition, FIG. 8 illustrates that one third island portion 31 is disposed between the first island portion 11 and the second island portion 21, but the disclosure is not limited thereto. In an embodiment, a plurality of third island portions 31, for example, two third island portions 31, may be disposed between the first island portion 11 and the second island portion 21. In this case, the first island portion 11, a third-1 island portion, a third-2 island portion, and the second island portion 21 may be sequentially disposed. In addition, the support column SC may be disposed in both the third-1 island portion and the third-2 island portion.

A protective column TC may be disposed on an upper portion (e.g., upper surface) of the second island portion 21. For example, the protective column TC may be disposed on an upper portion of the third organic insulating layer 213 of the second island portion 21. In an embodiment, a height of the protective column TC may be less than the height of the support column SC. That is, a height from an upper surface of the third organic insulating layer 213 to an upper surface of the protective column TC may be less than the height from the upper surface of the third organic insulating layer 213 to the upper surface of the support column SC. In addition, a height from a lower surface of the second island portion 21 to the upper surface of the protective column TC may be less than the height from the lower surface of the third island portion 31 to the upper surface of the support column SC.

Also, in an embodiment, the height of the protective column TC may be less than the height of the light-emitting diode 230. That is, the height from the upper surface of the third organic insulating layer 213 to the upper surface of the protective column TC may be less than the height from the upper surface of the third organic insulating layer 213 to the upper surface of the light-emitting diode 230. In addition, the height from the lower surface of the second island portion 21 to the upper surface of the protective column TC may be less than the height from the lower surface of the first island portion 11 to the upper surface of the light-emitting diode 230.

In an embodiment, the protective column TC may include the same material as the support column SC. In addition, the protective column TC may be disposed on the same layer as the support column SC and may be formed in the same process as the support column SC.

In an embodiment, such a protective column TC may be disposed not to overlap the circuit unit CP disposed in the second island portion 21 in a plan view. For example, the second island portion 21 may have an approximately rectangular shape. The protective column TC may include a plurality of protective columns, and the plurality of protective columns TC may be disposed along a periphery of the second island portion 21.

According to embodiments of the disclosure, the pressing plate may be supported in the non-display area NDA by the support column SC of the third island portion 31 adjacent to the second island portion 21. Accordingly, the support column SC may not be disposed in the second island portion 21, and the protective column TC having a lower height than that of the support column SC may be disposed. The pressing force of the pressing plate may be supported by the support column SC in the non-display area NDA, and the protective column TC may be a column configured to block the pressing plate from contacting the upper portion of the second island portion 21 instead of supporting the pressing plate. In addition, as the protective column TC is disposed not to overlap the circuit unit CP in a plan view, pressure damage to the circuit unit CP caused by being disposed on a lower portion of the protective column TC may be effectively prevented.

In an embodiment, the protective column TC may not be disposed on a side, which is adjacent to the third island portion 31, among four sides of the second island portion 21. In addition, a size of the protective column TC disposed on a side of the second island portion 21, which is distal to the third island portion 31, may be greater than a size of the protective column TC disposed on another side of the second island portion 21. In addition, according to an embodiment, the size of the protective column TC may be less than the size of the support column SC in a plan view.

The pressing plate may be applied with a greater pressing force in the second island portion 21 in a direction from the display area DA toward the non-display area NDA, that is, in a direction from the first island portion 11 toward the second island portion 21. As the protective column TC is disposed in a larger size in an area where the pressing force of the pressing plate is greater, the circuit unit CP of the second island portion 21 may be more effectively protected.

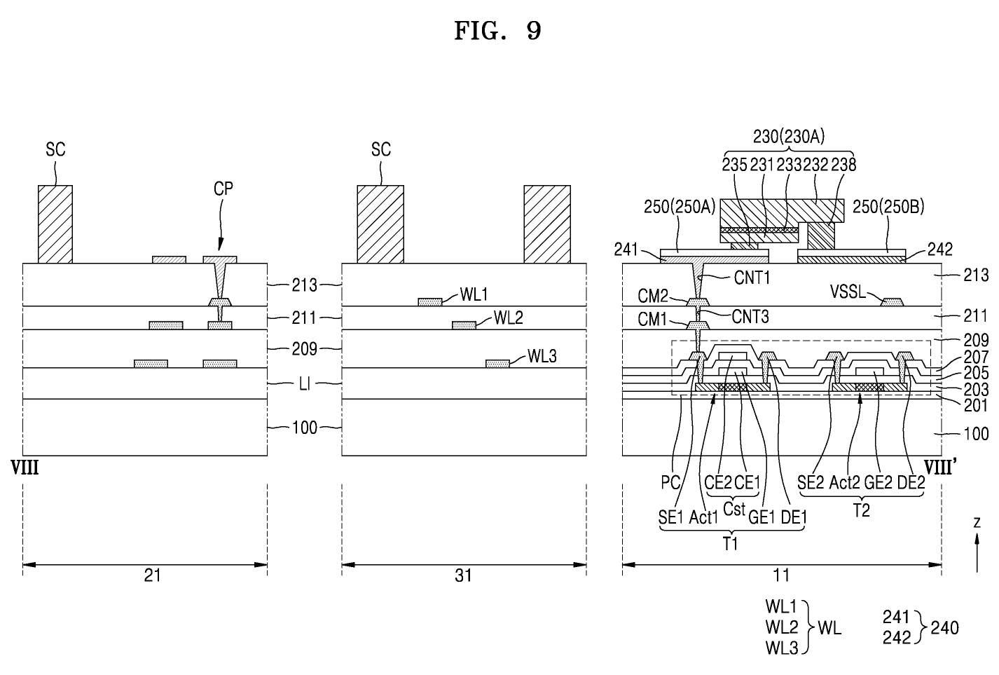

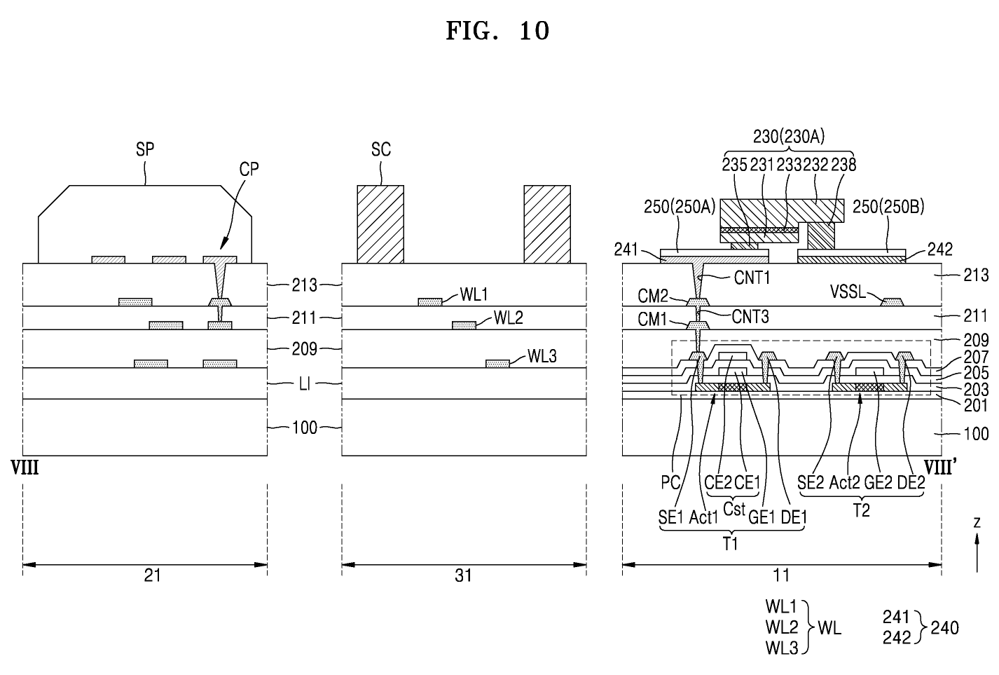

FIGS. 9 and 10 are cross-sectional views schematically illustrating a display apparatus according to other embodiments of the disclosure, corresponding to a cross-section taken along line VIII-VIII' of FIG. 7. A display apparatus according to an embodiment is similar to the display apparatus described above regarding FIG. 8, and thus only differences thereof are mainly described below.

Referring to FIG. 9, in an embodiment, the support column SC may also be disposed in the second island portion 21. The support column SC may be disposed on the upper portion of the second island portion 21. For example, the support column SC may be disposed on the upper portion of the third organic insulating layer 213 of the second island portion 21. In this case, the support column SC may be disposed not to overlap the circuit unit CP disposed in the second island portion 21 in a plan view. In addition, the support column SC disposed in the second island portion 21 may have the same height as the support column SC disposed in the third island portion 31. In this case, the support column SC of the second island portion 21 may support the pressing plate together with the support column SC of the third island portion 31. In this case, it may be understood that the support column SC disposed in the second island portion 21 may include the same material as the support column SC disposed in the third island portion 31, may be disposed on the same layer, and may be formed in the same process.

Referring to FIG. 10, in an embodiment, a support portion SP may be disposed in the second island portion 21 to support the pressing plate. The support portion SP may be disposed on the upper portion of the second island portion 21. For example, the support portion SP may be disposed on the upper portion of the third organic insulating layer 213 of the second island portion 21. The support portion SP may support the pressing plate, similarly to the support column SC. That is, the support portion SP may have the same height as the support column SC disposed in the third island portion 31. In this case, it may be understood that the support portion SP may include the same material as the support column SC disposed in the third island portion 31, may be disposed on the same layer, and may be formed in the same process.

In an embodiment, the support portion SP may be disposed to cover at least a portion of the circuit unit CP. That is, the support portion SP may be disposed to overlap at least a portion of the circuit unit CP in a plan view. The support portion SP may be disposed to cover the upper surface of the second island portion 21 and may have a tapered shape that becomes narrower toward the top. As the support portion SP is widely disposed on the upper surface of the second island portion 21, the pressing force may be distributed to the entire second island portion 21 while supporting the pressing plate. In addition, the support portion SP may prevent damage to the circuit unit CP by distributing the pressing force, even being disposed to overlap the circuit unit CP in a plan view.

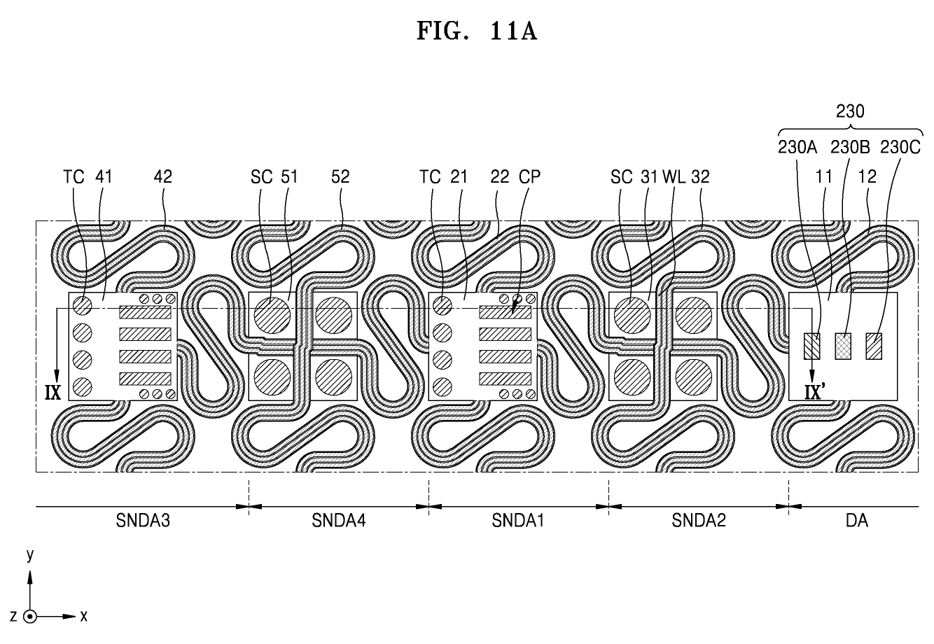

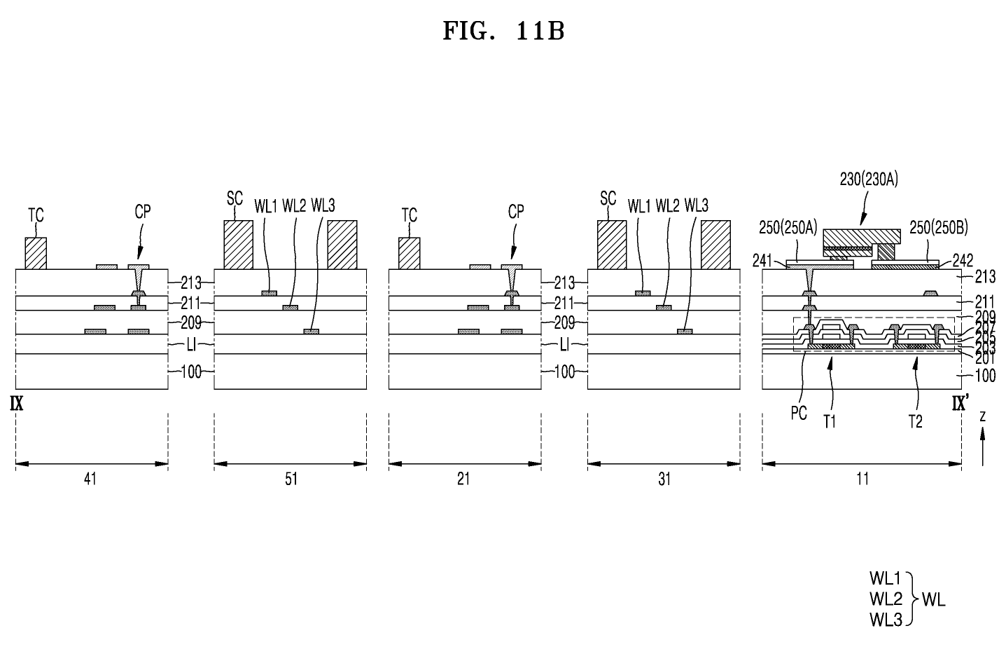

FIG. 11A is a plan view schematically illustrating a display apparatus according to an embodiment of the disclosure, and may be similar to FIG. 7. FIG. 11B is a cross-sectional view schematically illustrating a display apparatus according to an embodiment of the disclosure, corresponding to a cross-section taken along line IX-IX' of FIG. 11A, and may be similar to FIG. 8. A display apparatus according to an embodiment is similar to the display apparatuses described above, and thus only differences thereof are mainly described below.

Referring to FIGS. 11A and 11B, the first island portion 11 may be disposed in the display area DA, and the second island portion 21 and the third island portion 31 may be disposed in the non-display area NDA. In particular, the second island portion 21 may be disposed in the first sub-non-display area SNDA1, and the third island portion 31 may be disposed in the second sub-non-display area SNDA2 between the display area DA and the first sub-non-display area SNDA1.

In this case, in an embodiment, a third sub-non-display area SNDA3 may be defined outside the first sub-non-display area SNDA1, for example, on a side opposite to the display area DA. In addition, a fourth sub-non-display area SNDA4 may be defined between the first sub-non-display area SNDA1 and the third sub-non-display area SNDA3.

A fourth island portion 41 may be disposed in the third sub-non-display area SNDA3. A fifth island portion 51 may be disposed in the fourth sub-non-display area SNDA4. That is, the first island portion 11, the third island portion 31, the second island portion 21, the fifth island portion 51, and the fourth island portion 41 may be sequentially disposed in a direction from the display area DA toward the non-display area NDA. Although not illustrated in the drawing, it may be understood that the island portions may be connected to each other through bridge portions.

The fourth island portion 41 may have the same structure as the second island portion 21. For example, the fourth island portion 41 may have the same stacked structure as the second island portion 21, and may be an island portion in which the circuit unit CP is disposed. The protective column TC may be disposed in the fourth island portion 41, like the second island portion 21.

The fifth island portion 51 may have the same structure as the third island portion 31. For example, the fifth island portion 51 may have the same stacked structure as the third island portion 31, and may be an island portion in which the lines WL are disposed. The support column SC may be disposed in the fifth island portion 51, like the third island portion 31.

That is, an island portion in which the lines WL are disposed (for example, the third island portion 31 or the fifth island portion 51) and an island portion in which the circuit unit CP is disposed (for example, the second island portion 21 and the fourth island portion 41) may be alternately disposed. Accordingly, the pressing plate may be more stably supported by the support columns SC in the non-display area NDA, and damage caused by contact with the circuit unit CP may be more effectively prevented.

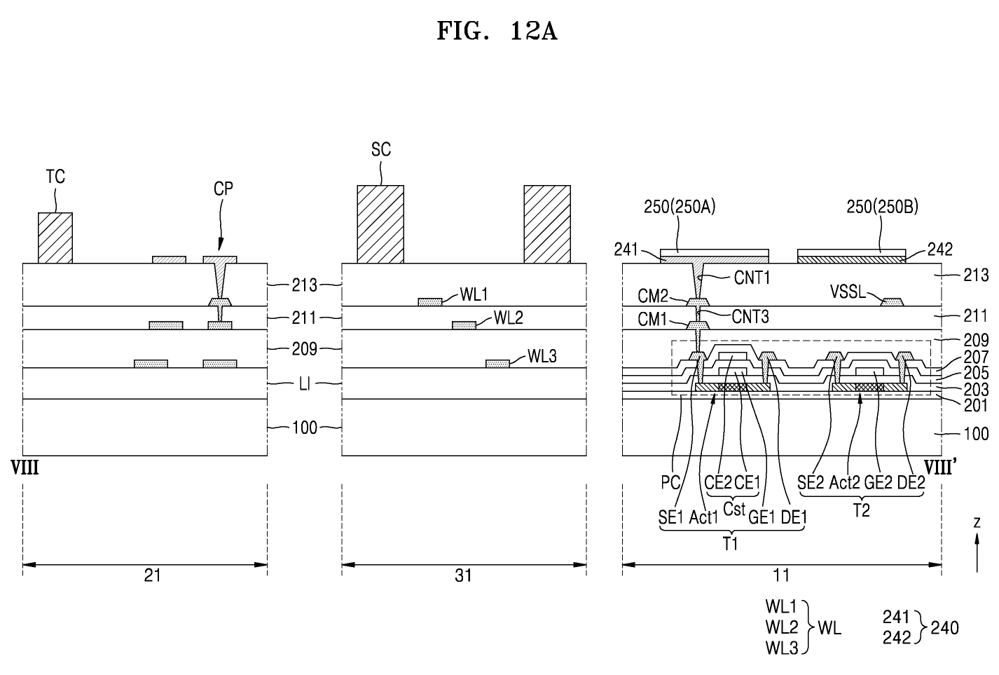

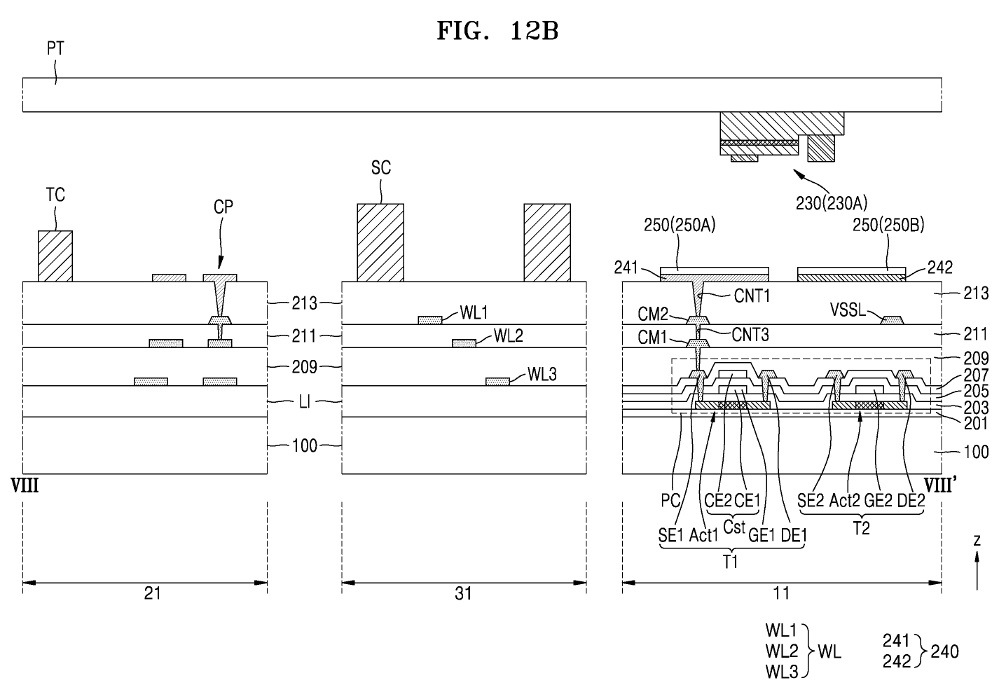

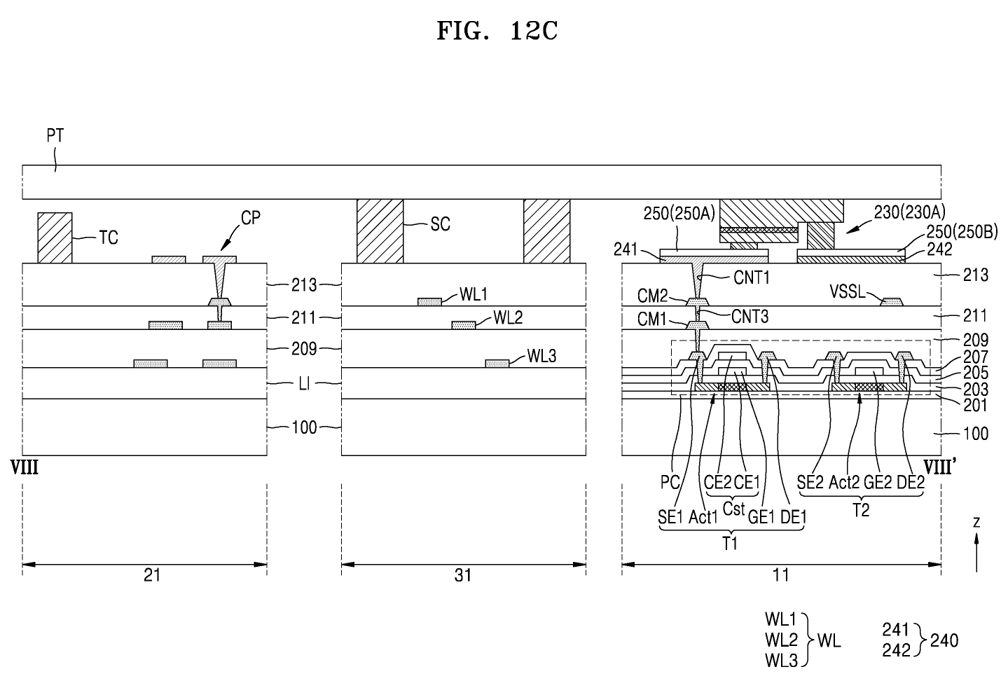

FIGS. 12A to 12C are diagrams schematically illustrating a method of manufacturing a display apparatus according to an embodiment of the disclosure. A method of manufacturing a display apparatus according to an embodiment may be used to manufacture the display apparatus described above, but is not limited thereto.

Referring to FIG. 12A, a display substrate may be prepared. The display substrate may mean the display apparatus 1 being manufactured. As described above, the display substrate may include the first island portion 11 disposed in the display area DA, and the second island portion 21 and the third island portion 31 disposed in the non-display area NDA.

The substrate 100 and insulating layers on the substrate 100 may be stacked in the first island portion 11. An electrode pad 240 and a bump metal 250 on the electrode pad 240 may be disposed on the insulating layers. The substrate 100 and the insulating layers on the substrate 100 may be stacked in the second island portion 21. The protective column TC may be disposed on the insulating layers. The substrate 100 and the insulating layers on the substrate 100 may be stacked in the third island portion 31. The support column SC may be disposed on the insulating layers.

Referring to FIG. 12B, the light-emitting diode 230 may be connected to the first island portion 11. In this case, a pressing plate PT may press an upper portion of the display substrate for a firm connection of the light-emitting diode 230. In this case, the pressing plate PT may cover an entire upper surface of the display substrate. For example, the pressing plate PT may cover the non-display area NDA as well as the display area DA.

Referring to FIG. 12C, the pressing plate PT may press the light-emitting diode 230 to the upper surface of the first island portion 11. In this case, a portion of the pressing plate PT, which corresponds to the non-display area NDA, may press the second island portion 21 and the third island portion 31, which are disposed in the non-display area NDA, by the pressing force. According to an embodiment of the disclosure, the support column SC disposed in the third island portion 31 may support the pressing plate PT to prevent the pressing plate PT from coming into contact with and damaging the upper surfaces of the second island portion 21 and the third island portion 31. In addition, the protective column TC of the second island portion 21 may be disposed to prevent the pressing plate PT from damaging the circuit unit CP of the second island portion 21 by being pressed toward the second island portion 21 even when being supported by the support column SC.

According to the method of manufacturing a display apparatus according to an embodiment of the disclosure, pressure generated during a bonding process of the light-emitting diode 230 may be distributed to be supported even in the non-display area NDA, thereby preventing defects in circuits or lines positioned in island portions.

The display apparatus 1 according to the embodiments described above may be used in various electronic devices that may provide images. Here, the electronic devices refer to devices that may provide images by using electricity.

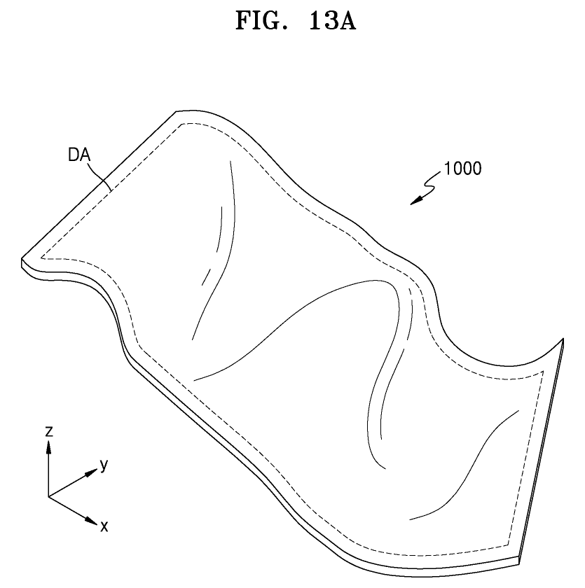

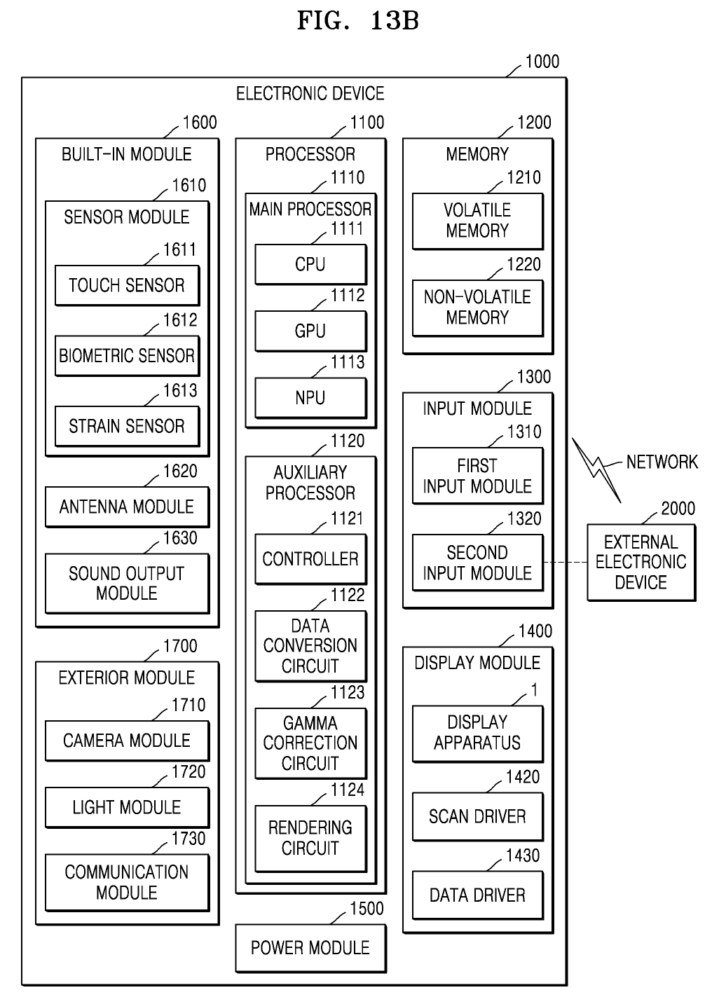

FIG. 13A is a perspective view schematically illustrating an electronic device 1000 including a display apparatus according to an embodiment of the disclosure, and FIG. 13B is a block diagram schematically illustrating the electronic device 1000 including the display apparatus 1 according to an embodiment of the disclosure.

Referring to FIG. 13A, the electronic device 1000 may freely be transformed three-dimensionally and provide a three-dimensional image surface through the display area DA. The electronic device 1000 being freely transformed three-dimensionally is distinguished from an operation of an electronic device having a rollable display device, such as a case in which the entire display area is recognized by a user while a portion of a rolled-up display area is recognized by the user and then another portion of the rolled-up display area is unfolded (or a case in which only a portion of the display area is recognized while the entire portion of the unfolded display area is recognized to the user and then the display area is rolled up). The electronic device 1000 according to embodiments of the disclosure may exhibit transformation such that the area of the entire display area DA increases or decreases again while the electronic device 1000 is transformed in an x direction, a y direction, and/or a z direction.

Referring to FIG. 13B, the electronic device 1000 may include a processor 1100, a memory 1200, an input module 1300, a display module 1400, a power module 1500, a built-in module 1600, and an exterior module 1700. According to an embodiment, the electronic device 1000 may have at least one of the components described above omitted, or one or more other components may be added. According to an embodiment, some of the components described above (for example, the built-in module 1600) may be integrated into another component (for example, the display module 1400).

The processor 1100 may execute software to control at least one other component (e.g., a hardware or software component) of the electronic device 1000 connected to the processor 1100 and may perform various data processing or calculations. According to an embodiment, as at least a part of data processing or calculation, the processor 1100 may store commands or data received from another component (e.g., the input module 1300, a sensor module 1610, or a communication module 1730) in volatile memory 1210, process commands or data stored in the volatile memory 1210, and store resulting data in non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphics processing unit (GPU) 1112, a communication processor (CP), and an image signal processor (ISP). The main processor 1110 may also further include a neural processing unit (NPU) 1113. An NPU is a processor specialized in processing of artificial intelligence models, and the artificial intelligence models may be created through machine learning. An artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the above, but is not limited to the examples described above. An artificial intelligence model may additionally or alternatively include a software structure in addition to a hardware structure. At least two of the processing units and processors described above may be implemented as a single integrated configuration (for example, a single chip) or may each be implemented as an independent configuration (for example, multiple chips).

The auxiliary processor 1120 may include a controller 1121. The controller 1121 may include an interface conversion circuit and a timing control circuit. The controller 1121 may receive an image signal from the main processor 1110 and convert a data format of the image signal to match the interface specifications with the display module 1400 to output the image data. The controller 1121 may output various types of control signals necessary for driving the display module 1400.

The auxiliary processor 1120 may further include data processing circuits such as a data conversion circuit 1122, a gamma correction circuit 1123, and a rendering circuit 1124. The data conversion circuit 1122 may receive image data from the controller 1121 and compensate for the image data so that an image is displayed at a desired brightness according to the characteristics of the electronic device 1000 or the user's settings or convert the image data for reduction in power consumption or compensation for afterimages. The gamma correction circuit 1123 may convert image data or a gamma reference voltage so that an image displayed on the electronic device 1000 has a desired gamma characteristic. The rendering circuit 1124 may receive image data from the controller 1121 and render the image data by considering pixel arrangements of the display apparatus 1 applied to the electronic device 1000. At least one of the data conversion circuit 1122, the gamma correction circuit 1123, and the rendering circuit 1124 may be integrated into another component (for example, the main processor 1110 or the controller 1121). In an embodiment, the auxiliary processor 1120 may be integrated into a data driver 1430.

The memory 1200 may store various pieces of data used by at least one component (e.g., the processor 1100 or the sensor module 1610) of the electronic device 1000 and input data or output data with respect to commands related thereto. The memory 1200 may include at least one or more of the volatile memory 1210 and the non-volatile memory 1220.

The input module 1300 may receive commands or data to be used in a component of the electronic device 1000 (e.g., the processor 1100, the sensor module 1610, or a sound output module 1630), from the outside of the electronic device 1000 (e.g., a user or an external electronic device 2000).

The input module 1300 may include a first input module 1310 to which a command or data is input from the user and a second input module 1320 to which a command or data is input from the external electronic device 2000.

The first input module 1310 may include a microphone, a mouse, a keyboard, or a pen (e.g., a passive pen or an active pen). The first input module 1310 may include a mechanical input unit or a touch input unit such as a button, a dome switch, a jog wheel, a jog switch, or the like positioned on a back surface or a side surface of the electronic device 1000. The touch input unit may include a touch screen layer of the display apparatus 1.

The second input module 1320 may be connected to various types of external electronic devices 2000 connected to the electronic device 1000 in a wired or wireless manner. According to an embodiment, the second input module 1320 may include a high definition multimedia interface (HDMI), a universal serial bus (USB) interface, a secure digital (SD) card interface, or an audio interface. The second input module 1320 may include a connector capable of physically connecting the electronic device 1000 to the external electronic device 2000, for example, an HDMI connector, a USB connector, an SD card connector, or an audio connector (e.g., a headphones connector). The electronic device 1000 may perform appropriate control related to the connected external electronic device 2000 in response to the external electronic device 2000 being connected to the second input module 1320.

The display module 1400 visually provides information to the user. The display module 1400 may include the display apparatus 1, a scan driver 1420, and the data driver 1430.

The display apparatus 1 displays (outputs) information processed by the electronic device 1000. The display apparatus 1 may display execution screen information of an application driven by the electronic device 1000 or user interface (UI) or graphical user interface (GUI) information according to the execution screen information.

The scan driver 1420 may be mounted in the display apparatus 1 as a driving chip. Alternatively, the scan driver 1420 may be directly formed in the display apparatus 1. For example, the scan driver 1420 may include an amorphous silicon TFT gate driver circuit (ASG), a low temperature polycrystalline silicon (LTPS) TFT gate driver circuit, or an oxide semiconductor TFT gate driver circuit (OSG) embedded in the display apparatus 1. The scan driver 1420 receives a control signal from the controller 1121 and outputs a scan signal to the display apparatus 1 in response to the control signal.

The display apparatus 1 may further include an emission control driver. The emission control driver outputs an emission control signal to the display apparatus 1 in response to a control signal received from the controller 1121. The emission control driver may be formed separately from the scan driver 1420 or may be integrated into the scan driver 1420.

The data driver 1430 receives a control signal from the controller 1121, converts image data into data voltages in a form of analog voltages in response to the control signal, and then outputs the data voltages to the display apparatus 1.

The data driver 1430 may be integrated with some components of the auxiliary processor 1120. For example, the data driver 1430 may be provided as a timing controller embedded driver integrated circuit (IC) including the controller 1121.

The power module 1500 supplies power to the components of the electronic device 1000. The power module 1500 may include a battery that charges the power voltage. In addition, the power module 1500 may have a connection port, and the connection port may be included in the second input module 1320 to which an external charger that supplies power to charge the battery is connected. Alternatively, the power module 1500 may include a wireless power transmission/reception member to enable wireless charging of the battery. The wireless power transmission/reception member may include a plurality of antenna radiators in a coil shape. The power module 1500 may include a power management integrated circuit (PMIC). The PMIC supplies optimized power to each component of the electronic device 1000.

The electronic device 1000 may further include the built-in module 1600 and the exterior module 1700. The built-in module 1600 may include the sensor module 1610, an antenna module 1620, and the sound output module 1630. The exterior module 1700 may include a camera module 1710, a light module 1720, and/or the communication module 1730.

The sensor module 1610 may include touch electrodes and a touch sensor driver of a touch screen layer of the display apparatus 1. The sensor module 1610 may sense an input by the user's body or an input by a pen and generate an electrical signal or data value corresponding to the input. The sensor module 1610 may include at least one of a touch sensor 1611, a biometric sensor 1612, and a strain sensor 1613.

The touch sensor 1611 may generate a data value corresponding to coordinate information of an input by the user's body (e.g., a finger or the like) or an input by a pen. The touch sensor 1611 may generate an amount of change in capacitance, an amount of change in pressure, or an amount of change in electromagnetic field as a data value.

The biometric sensor 1612 may generate data values recognizing a part of the user's body (e.g., fingerprints, irises, face, or the like.) or data values corresponding to body information (e.g., blood pressure, moisture, heart rate, body composition, or the like). The biometric sensor 1612 may use an optical method, an ultrasonic method, or a capacitive method.

The strain sensor 1613 may include layers, patterns, or lines of which a measurable physical quantity changes according to the stretching and recovering of the display apparatus 1. For example, the strain sensor 1613 may include lines of which the resistance and/or capacitance changes due to the stretching and recovering of the display apparatus 1. In another embodiment, the strain sensor 1613 may include an optical layer or optical pattern of which the transmittance and/or reflectance changes due to the stretching and recovering of the display apparatus 1.

Based on the physical quantity according to the stretching and recovering of the display apparatus 1, which is measured by the strain sensor 1613, the electronic device 1000 may improve the image quality of an image implemented by the display apparatus 1 or control the display apparatus 1. A control operation of the display apparatus 1 may include, for example, an operation of displaying an operation image to protect the display apparatus 1, an operation of cutting off a voltage for driving the display apparatus 1, or an operation of stopping a stretching and recovering operation of the display apparatus 1.

In an embodiment, at least one of the touch sensor 1611, the biometric sensor 1612, and the strain sensor 1613 may be built into the display apparatus 1. For example, at least one of the touch sensor 1611, the biometric sensor 1612, and the strain sensor 1613 may be formed through a process that is continuous with a process of forming pixel driving circuit units and/or light-emitting elements of the display apparatus 1. Therefore, the display apparatus 1 may function as one of the input modules 1300 providing an input interface between the electronic device 1000 and the user and at the same time, may function as the display module 1400 providing an output interface between the electronic device 1000 and the user.

In an embodiment, at least two of the touch sensor 1611, the biometric sensor 1612, and the strain sensor 1613 may be formed to be integrated into one sensing panel through the same process. In an embodiment, the sensing panel may be arranged between the display apparatus 1 and a window cover disposed on a front surface of the display apparatus 1, but the disclosure is not limited thereto.

The antenna module 1620 may include one or more antennas for transmitting signals or power to the outside or receiving signals or power from the outside. According to an embodiment, the communication module 1730 may transmit a signal to an external electronic device or receive a signal from the external electronic device through an antenna suitable for a communication method. An antenna pattern of the antenna module 1620 may also be integrated into one component of the display module 1400 (e.g., the display apparatus 1) or the biometric sensor 1612.

The sound output module 1630 is a device for outputting sound signals to the outside of the electronic device 1000, which may output sound data received from the communication module 1730 in a call signal reception mode, call mode, recording mode, voice recognition mode, or broadcast reception mode or sound data stored in the memory 1200. The sound output module 1630 may output sound signals related to functions (for example, a call signal reception sound, a message reception sound, or the like) performed by the electronic device 1000. The sound output module 1630 may include a receiver and a speaker. At least one of the receiver and the speaker may be a sound generating device which is attached to a rear surface of the display apparatus 1 and vibrates the display apparatus 1 to output sound. The sound generating device may be a piezoelectric element or a piezoelectric actuator which contracts and expands according to an electrical signal, or may be an exciter that vibrates the display apparatus 1 by generating a magnetic force using a voice coil.

The camera module 1710 may capture still images and videos. According to an embodiment, the camera module 1710 may include one or more lenses, image sensors, or image signal processors. The camera module 1710 may further include an infrared camera that may measure the presence or absence of the user, the user's position, the line of sight of the user, or the like.

The light module 1720 may output a signal to notify the occurrence of an event by using light of a light source or provide light for image acquisition. Here, examples of the occurrences of events may include reception of a message, reception of a call signal, missing a call, a notification, a calendar reminder, reception of an email, or notification of battery charge level information. The light module 1720 may include a light-emitting diode or xenon lamp. The light module 1720 may emit light of a single color or multiple colors to the front surface or rear surface of the electronic device 1000. The light module 1720 may operate in conjunction with the camera module 1710 or independently.

The communication module 1730 may support establishment of a wired or wireless communication channel between the electronic device 1000 and the external electronic device 2000 and performance of communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module or a power line communication module. The communication module 1730 may transmit and receive wireless signals on the Internet by using at least one of Wireless LAN (WLAN), Wireless-Fidelity (Wi-Fi), Wi-Fi Direct, and Digital Living Network Alliance (DLNA) technologies. Also, the communication module 1730 may support short-range communication by using at least one of Bluetooth™, radio frequency identification (RFID), infrared data association (IrDA), ultrawideband (UWB), ZigBee, near-field communication (NFC), Wi-Fi, Wi-Fi Direct, and wireless universal serial bus (USB) technology. The various types of communication module 1730 described above may be implemented as a single chip or as separate chips.

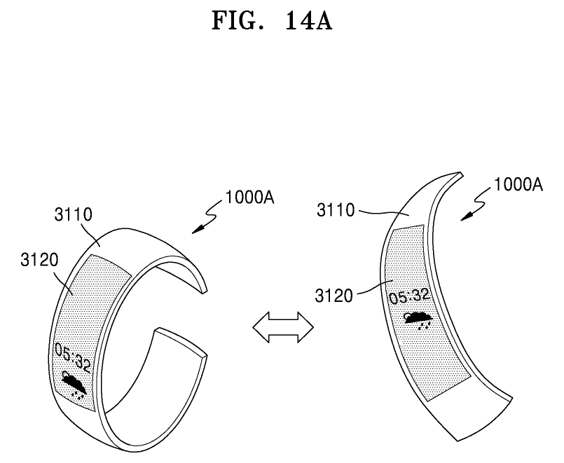

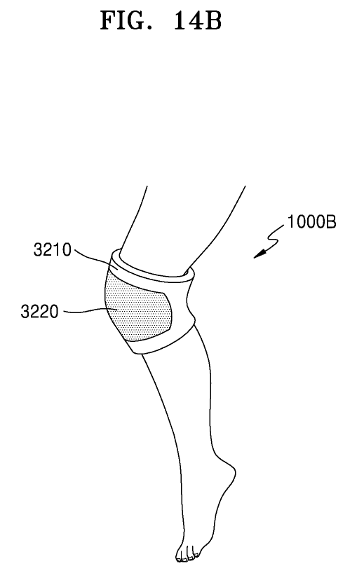

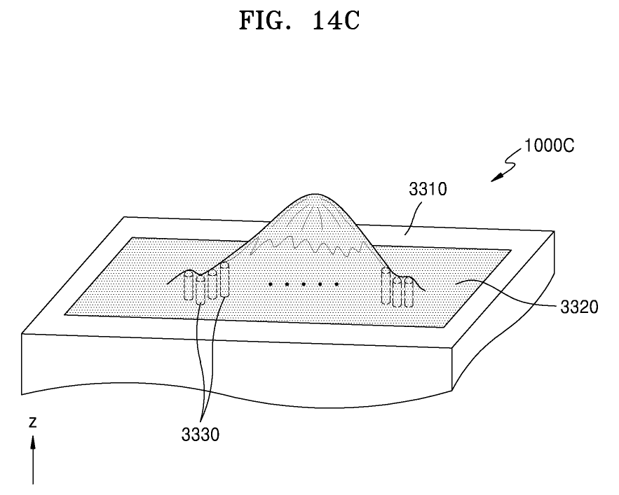

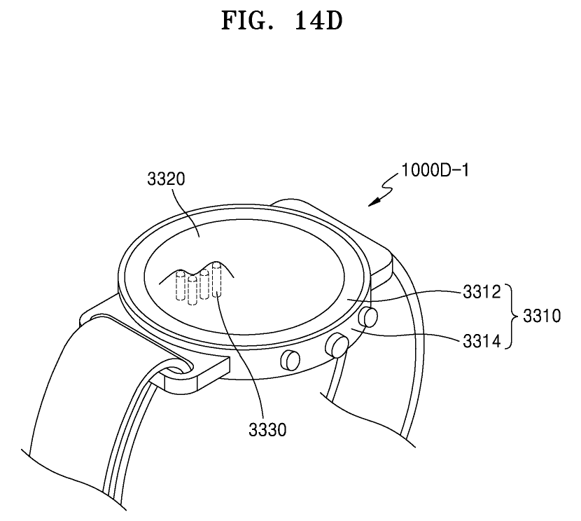

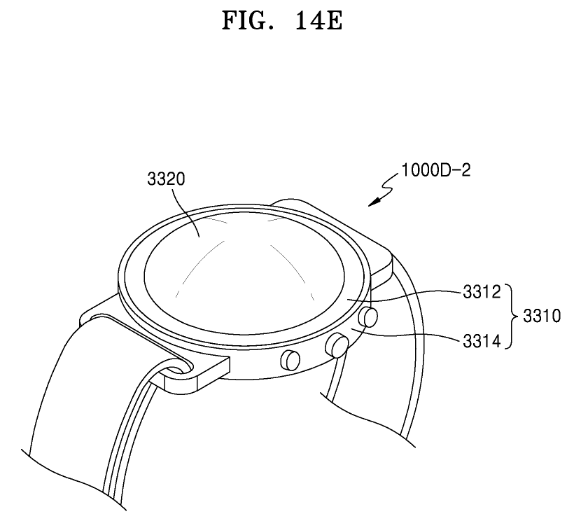

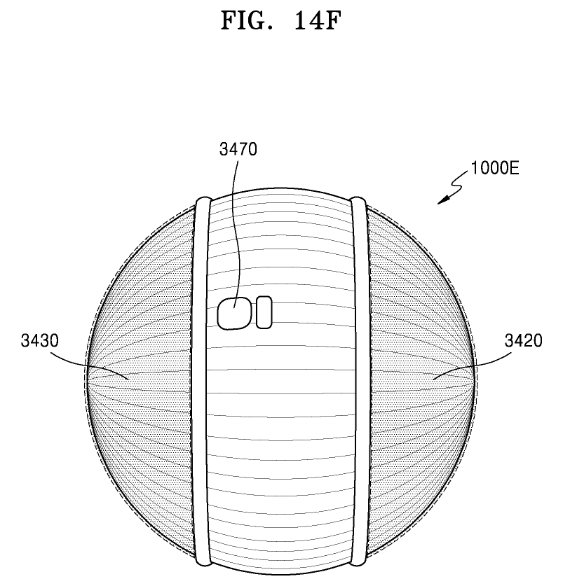

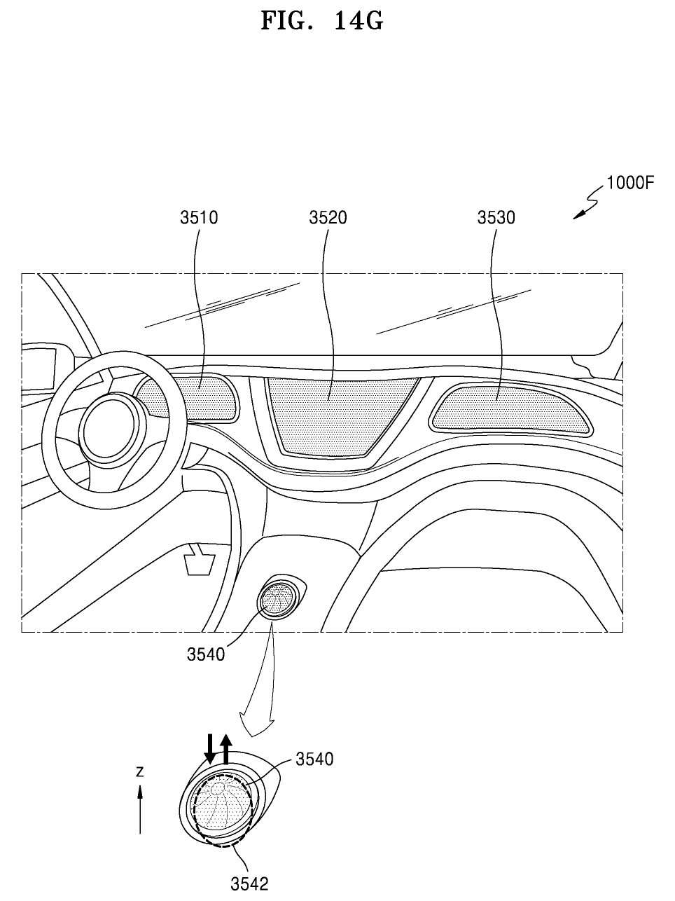

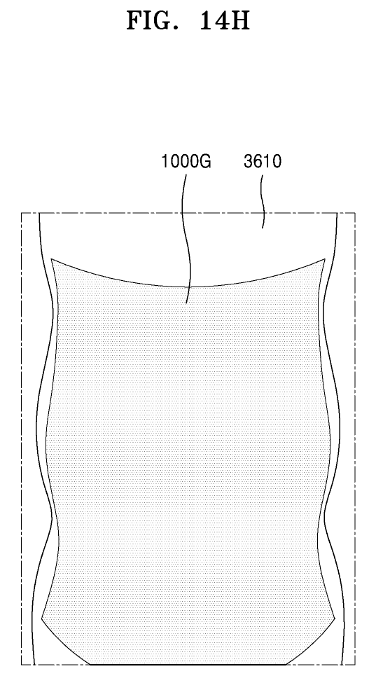

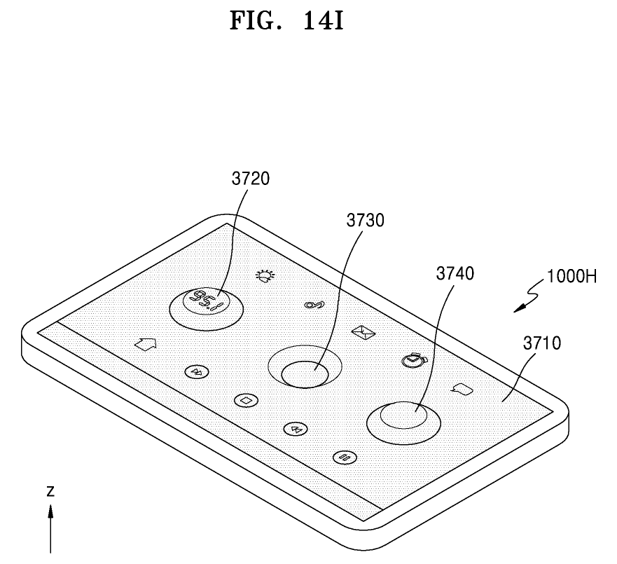

FIGS. 14A to 14I are schematic perspective views showing embodiments of an electronic device including a display apparatus according to an embodiment of the disclosure, respectively.

Referring to FIG. 14A, a display apparatus according to an embodiment may be used in a wearable electronic device 1000A which may be worn on a part of a user's body. The wearable electronic device 1000A may include a body portion 3110 and a display portion 3120 provided in the body portion 3110. A display apparatus according to embodiments of the disclosure may be used as the display portion 3120 of the wearable electronic device 1000A. As shown in FIG. 14A, the wearable electronic device 1000A may be transformable. In an embodiment, the wearable electronic device 1000A may be used as a smartwatch or a smartphone depending on the user's choice.

FIG. 14B shows a medical electronic device 1000B. In an embodiment, the medical electronic device 1000B may include a body portion 3210 and a light-emitting portion 3220. A display apparatus according to embodiments of the disclosure may be used as the light-emitting portion 3220 of the medical electronic device 1000B. The light-emitting portion 3220 may emit light of a certain wavelength band (e.g., infrared light, visible light ray, or the like) to the body of a patient. In an embodiment, the body portion 3210 may include a stretchable and recoverable fiber material and may have a structure that may be worn on the user's body.

FIG. 14C shows an educational electronic device 1000C. In an embodiment, the educational electronic device 1000C may include a display portion 3320 provided in a body portion 3310. The display portion 3320 may use a display apparatus according to embodiments of the disclosure. The display portion 3320 may provide images, such as a sea with waves, a mountain covered with snow, or a volcano with flowing lava, and In this case, the display portion 3320 may extend in a height direction (e.g., a z direction) by reflecting the height of the waves, the mountain, or the volcano. In some embodiments, a portion of the display portion 3320 may three-dimensionally show the movement of lava by sequentially changing the height along a direction in which the lava flows. The educational electronic device 1000C may include a plurality of pins (or stroke portions) 3330 arranged on the rear surface of the display portion 3320 so that the display portion 3320 may be stretched in the height direction. While the pins 3330 move along a third direction (e.g., a z direction or a -z direction), an image displayed on the display portion 3320 may be implemented to have a three-dimensional height. FIG. 14C shows the educational electronic device 1000C, but the use is not limited as long as the device provides certain image information.

FIGS. 14D and 14E show that a display apparatus is used in wearable electronic devices 1000D-1 and 1000D-2, such as a smartwatch.

In an embodiment, as shown in FIG. 14D, a display apparatus corresponding to the display portion 3320 of the wearable electronic device 1000D-1 is three-dimensionally stretchable and thus may provide the user with various pieces of haptic information in addition to visual information through images. In an embodiment, the wearable electronic device 1000D-1 may provide haptic information, such as a braille display for visually impaired or tactile stimulation linked to an image, by using a plurality of pins (or stroke portions) 3330 arranged below the display portion 3320. The display apparatus forming the display portion 3320 is three-dimensionally stretchable and thus may provide the user with the haptic information described above. The wearable electronic device 1000D-1 includes the display apparatus forming the display portion 3320 and a housing 3314 in which pins (or strokes portions) 3330 are accommodated, and may include a body portion 3310 including a frame 3312 that may be coupled to a housing 3314 with the display apparatus therebetween. In some embodiments, the frame 3312 may be integrally formed with the housing 3314.

The wearable electronic device 1000D-2 of FIG. 14E may include a body portion 3310 and the display portion 3320 accommodated in the body portion 3310 and capable of providing visual information. In some embodiments, a display apparatus corresponding to the display portion 3320 may include a dome-shaped display portion 3320 that is three-dimensionally stretchable. In an embodiment, in a process of manufacturing the wearable electronic device 1000D-2, a display apparatus may be assembled into a body frame having a dome shape, and In this case, the display apparatus is three-dimensionally stretchable and thus may be assembled in a stretched state according to the shape of the body frame having the dome shape.

FIG. 14F shows that an electronic device 1000E according to an embodiment of the disclosure includes a robot. The robot may recognize movement or objects by using a camera module 3470 and may display certain images through display portions 3420 and 3430.

In some embodiments, as described above, because a display apparatus according to an embodiment of the disclosure may be stretched in various directions, the display apparatus may be assembled into a body frame having a hemispherical shape, and accordingly, the robot may include the display portions 3420 and 3430 having hemispherical shapes.

FIG. 14G shows a vehicle display apparatus 1000F as an electronic device according to an embodiment of the disclosure. The vehicle display apparatus 1000F may include a cluster 3510, a center information display (CID) 3520, and/or a co-driver display 3530. Because a display apparatus according to an embodiment of the disclosure may be stretched in various directions, the display apparatus may be used in the cluster 3510, the CID 3520, and/or the co-driver display 3530 regardless of the shape of the internal frame of the vehicle.

FIG. 14G shows that the cluster 3510, the CID 3520, and the co-driver display 3530 are separated from each other, but the disclosure is not limited thereto. In another embodiment, two or more selected from the cluster 3510, the CID 3520, and the co-driver display 3530 may be integrally connected to each other.

In some embodiments, the vehicle display apparatus 1000F may include a button 3540 that may display a certain image. Referring to the enlarged view of FIG. 14G, the button 3540 having a hemispherical shape may include an object 3542 that provides the feeling of using while moving in the z direction or the -z direction, and a display apparatus disposed on the object 3542. In some embodiments, when the object 3542 has a three-dimensionally rounded surface, the display apparatus may also have a three-dimensionally rounded surface.

FIG. 14H shows that an electronic device according to an embodiment of the disclosure is an advertising or exhibiting electronic device 1000G. In some embodiments, the advertising or exhibiting electronic device 1000G may be installed on a fixed structure 3610, such as a wall or pillar. When the structure 3610 includes an uneven surface as shown in FIG. 14H, the advertising or exhibiting electronic device 1000G may be disposed along the uneven surface of the structure 3610. In some embodiments, the advertising or exhibiting electronic device 1000G may be installed on the structure 3610 by using a heat shrink film or the like.

FIG. 14I shows that an electronic device 1000H according to an embodiment of the disclosure is a controller. The controller may include an image-type button. For example, the controller may include first to third button areas 3720, 3730, and 3740 in which a partial area of a display portion 3710 protrudes in a z direction or a -z direction (or is depressed in the z direction). In some embodiments, the first and third button areas 3720 and 3740 may protrude in the z direction, and the second button area 3730 may protrude in the -z direction (or may be depressed in the z direction).

Although the disclosure has been described with reference to the embodiments shown in the drawings, there are merely examples. Those skilled in the art will readily appreciate that various modifications and equivalent other embodiments are possible from the embodiments. Accordingly, the true technical protection scope of the disclosure should be defined based on the attached claims.

### EXPLANATION OF REFERENCE NUMERALS

1: Display apparatus

11: First island portion

21: Second island portion

31: Third island portion

41: Fourth island portion

51: Fifth island portion

100: Substrate

SC: support column

TC: Protective column

What is claimed is:

1. A display apparatus comprising a display area and a non-display area outside the display area, the display apparatus comprising:
a first island portion positioned in the display area and in which a light-emitting diode is disposed;
a second island portion positioned in the non-display area and in which a circuit unit is disposed;
a third island portion positioned between the first island portion and the second island portion in the non-display area and in which a line electrically connecting the light- emitting diode to the circuit unit is disposed; and
a support column disposed on an upper surface of the third island portion.

2. The display apparatus of claim 1, wherein a height from a lower surface of the third island portion to an upper surface of the support column is greater than a height from a lower surface of the first island portion to an upper surface of the light- emitting diode.

3. The display apparatus of claim 1, wherein, in a plan view, the support column is disposed not to overlap the line.

4. The display apparatus of claim 1, wherein the support column comprises an organic material.

5. The display apparatus of claim 1, wherein the support column is provided in plurality, and the plurality of support columns are disposed adjacent to vertices of the third island portion, respectively, in a plan view.

6. The display apparatus of claim 1, further comprising a protective column disposed on an upper surface of the second island portion.

7. The display apparatus of claim 6, wherein a height from a lower surface of the second island portion to an upper surface of the protective column is less than a height from a lower surface of the third island portion to an upper surface of the support column.

8. The display apparatus of claim 6, wherein, in a plan view, the protective column is disposed not to overlap the circuit unit.

9. The display apparatus of claim 6, wherein the protective column is provided in plurality, and the plurality of protective columns are disposed along a periphery of the second island portion in a plan view.

10. The display apparatus of claim 6, wherein the protective column comprises a same material as the support column.

11. The display apparatus of claim 6, wherein each of the second island portion and the third island portion comprises a substrate and an insulating layer covering the substrate, and each of the support column and the protective column is disposed on the insulating layer.

12. The display apparatus of claim 1, further comprising a support portion disposed on an upper surface of the second island portion and covering the circuit unit.

13. The display apparatus of claim 12, wherein the support portion comprises a same material as the support column.

14. The display apparatus of claim 1, further comprising a fourth island portion having a same structure as the second island portion and a fifth island portion having a same structure as the third island portion,
wherein the first island portion, the third island portion, the second island portion, the fifth island portion, and the fourth island portion are sequentially disposed in a direction from the display area toward the non-display area.

15. A method of manufacturing a display apparatus, comprising:
preparing a display substrate comprising a first island portion positioned in a display area, a second island portion positioned in a non-display area outside the display area, and a third island portion between the first island portion and the second island portion;
disposing a support column on an upper surface of the third island portion;
disposing a protective column on an upper surface of the second island portion;
disposing a light-emitting diode on an upper surface of the first island portion; and
pressing the display substrate with a pressing plate.

16. The method of claim 15, wherein the pressing plate presses the light- emitting diode in the display area and is supported by the support column in the non- display area.

17. The method of claim 15, wherein a height from a lower surface of the third island portion to an upper surface of the support column is greater than a height from a lower surface of the first island portion to an upper surface of the light-emitting diode.

18. The method of claim 15, wherein a height from a lower surface of the second island portion to an upper surface of the protective column is less than a height from a lower surface of the third island portion to an upper surface of the support column.

19. The method of claim 15, wherein a circuit unit is disposed in the second island portion, and a line electrically connecting the circuit unit to the first island portion is disposed in the third island portion.

20. An electronic device comprising a display portion, the electronic device comprising:
a display apparatus corresponding to the display portion; and
a frame accommodating the display apparatus,
wherein the display apparatus comprises a display area and a non-display area outside the display area, the display apparatus comprises a first island portion positioned in the display area and in which a light-emitting diode is disposed;
a second island portion positioned in the non-display area and in which a circuit unit is disposed;
a third island portion positioned between the first island portion and the second island portion in the non-display area and in which a line electrically connecting the light- emitting diode to the circuit unit is disposed; and
a support column disposed on an upper surface of the third island portion.
